(19) United States
(12) Patent Application Publication
(10) Pub. No.: US 2025/0078911 A1
(43) Pub. Date: Mar. 6, 2025

(54) METHODS OF FORMING MICROELECTRONIC DEVICES, AND RELATED MICROELECTRONIC DEVICES AND MEMORY DEVICES

(71) Applicant: Micron Technology, Inc., Boise, ID (US)

(72) Inventors: Fatma Arzum Simsek-Ege, Boise, ID (US); Haitao Liu, Boise, ID (US); David A. Daycock, Boise, ID (US)

(21) Appl. No.: 18/745,943

(22) Filed: Jun. 17, 2024

Related U.S. Application Data
(60) Provisional application No. 63/580,922, filed on Sep. 6, 2023.

(51) Int. Cl. G11C 11/4097; G11C 11/408; G11C 11/4091; H10B 12/00

(52) U.S. Cl. CPC G11C 11/4097; G11C 11/4085; G11C 11/4091; H10B 12/09; H10B 12/312; H10B 12/482; H10B 12/485; H10B 12/50

(57) ABSTRACT

A microelectronic device includes memory cells, hieratical digit line (HDL) structures, and sense amplifier (SA) devices. The memory cells are within an array region and respectively include an access device and a storage node device vertically underlying and coupled to the access device. The HDL structures are within the array region and vertically overlie and are coupled to the memory cells. The HDL structures respectively include a lower section, an upper section vertically overlying and at least partially horizontally offset from the lower section, and a middle section vertically extending from and between the lower section and the upper section. The SA devices are within the array region and vertically overlie and are coupled to the HDL structures. Related methods, memory devices, and electronic systems are also described.

### CROSS-REFERENCE TO RELATED APPLICATION

This application claims the benefit under 35 U.S.C. § 119(e) of U.S. Provisional Patent Application Ser. No. 63/580,922, filed Sep. 6, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices and memory devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, volatile memory devices. One type of volatile memory device is a dynamic random access memory (DRAM) device. A DRAM device may include a memory array including DRAM cells arranged rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit lines and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit lines and word lines coupled to the DRAM cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the DRAM device.

### BRIEF DESCRIPTION OF THE DRAWINGS

FIG. 1 is a simplified plan view of a microelectronic device structure at a processing stage of a method of forming a microelectronic device, in accordance with embodiments of the disclosure.

FIGS. 2A through 2C are simplified, partial vertical cross-sectional views of an array region (FIG. 2A), a word line (WL) exit region (FIG. 2B), and a peripheral region (FIG. 2C) of the microelectronic device structure shown in FIG. 1 at the processing stage of FIG. 1.

FIGS. 3A through 3C are simplified, partial vertical cross-sectional views of the array region (FIG. 3A), the WL exit region (FIG. 3B), and the peripheral region (FIG. 3C) collectively shown in FIGS. 2A through 2C at another processing stage of the method of forming the microelectronic device following the processing stage of FIGS. 2A through 2C.

FIGS. 4A through 4E are simplified, partial longitudinal cross-sectional views (FIGS. 4A, 4B, 4D, and 4E) and a simplified partial top-down vie (FIG. 4C) of the array region (FIGS. 4A through 4C), the WL exit region (FIG. 4D), and the peripheral region (FIG. 4E) collectively shown in FIGS. 3A through 3C at another processing stage of the method of forming the microelectronic device following the processing stage of FIGS. 3A through 3C.

FIGS. 5A through 5D are simplified, partial longitudinal cross-sectional views of the array region (FIGS. 5A and 5B), the WL exit region (FIG. 5C), and the peripheral region (FIG. 5D) collectively shown in FIGS. 4A through 4E at another processing stage of the method of forming the microelectronic device following the processing stage of FIGS. 4A through 4E.

FIGS. 6A through 6D are simplified, partial longitudinal cross-sectional views of the array region (FIGS. 6A and 6B), the WL exit region (FIG. 6C), and the peripheral region (FIG. 6D) collectively shown in FIGS. 5A through 5D at another processing stage of the method of forming the microelectronic device following the processing stage of FIGS. 5A through 5D.

FIGS. 7A through 7D are simplified, partial longitudinal cross-sectional views of the array region (FIGS. 7A and 7B), the WL exit region (FIG. 7C), and the peripheral region (FIG. 7D) collectively shown in FIGS. 4A through 4E at another processing stage of a method of forming a microelectronic device following the processing stage of FIGS. 4A through 4E, in accordance with additional embodiments of the disclosure.

FIG. 8 is a schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical valuc.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., GaxIn_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnxInyZn,O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

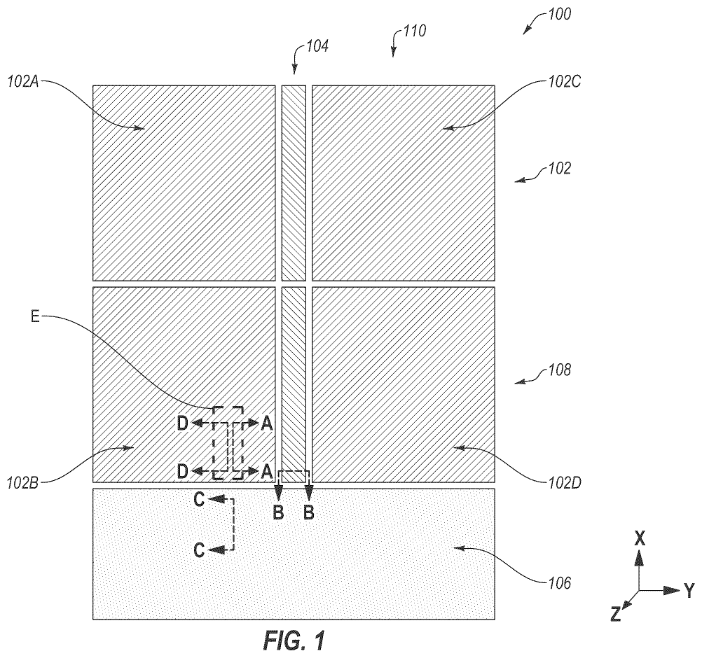

FIGS. 1 through 6D are various views (described in further detail below) illustrating different processing stages of a method of forming a microelectronic device (e.g., a memory device, such as a DRAM device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device. With the description provided below, it will be readily apparent to one of ordinary skill in the art that the methods and structures described herein may be used to form various devices and electronic systems.

FIG. 1 shows a simplified plan view of a first microelectronic device structure 100 (e.g., a first wafer, a first die) at an early processing stage of a method of forming a microelectronic device (e.g., a memory device, such as a DRAM device), in accordance with embodiments of the disclosure. As shown in FIG. 1, the first microelectronic device structure 100 may be formed to include array regions 102, word line (WL) exit regions 104 (also referred to as “word line (WL) contact socket regions”) interposed between pairs of the array regions 102 horizontally neighboring one another in the Y-direction, and one or more peripheral regions 106 (also referred to as “socket regions” and “back-end-of-line (BEOL) contact socket regions”) horizontally neighboring some of the array regions 102 in one or more of the Y-direction and the X-direction orthogonal to the Y-direction. The array regions 102, the WL exit regions 104, and the peripheral regions 106 are each described in further detail below.

The array regions 102 of the first microelectronic device structure 100 include horizontal areas of the first microelectronic device structure 100 configured to have arrays of memory cells (e.g., arrays of DRAM cells) within horizontal areas thereof, as described in further detail below. The first microelectronic device structure 100 may include a desired quantity and distribution of the array regions 102. For clarity and case of understanding of the drawings and related description, FIG. 1 depicts the first microelectronic device structure 100 as including four (4) array regions 102: a first array region 102A, a second array region 102B, a third array region 102C, and a fourth array region 102D. The second array region 102B may horizontally neighbor the first array region 102A in the X-direction, and may horizontally neighbor the fourth array region 102D in the Y-direction; the third array region 102C may horizontally neighbor the first array region 102A in the Y-direction, and may horizontally neighbor the fourth array region 102D in the X-direction; and the fourth array region 102D may horizontally neighbor the third array region 102C in the X-direction, and may horizontally neighbor the second array region 102B in the Y-direction. In additional embodiments, the first microelectronic device structure 100 is formed to include a different quantity and/or a different distribution of array regions 102. For example, the first microelectronic device structure 100 may be formed to include greater than four (4) array regions 102, such as greater than or equal to eight (8) array regions 102, greater than or equal to sixteen (16) array regions 102, greater than or equal to thirty-two (32) array regions 102, greater than or equal to sixty-four (64) array regions 102, greater than or equal to one hundred twenty-eight (128) array regions 102, greater than or equal to two hundred fifty-six (256) array regions 102, greater than or equal to five hundred twelve (512) array regions 102, or greater than or equal to one thousand twenty-four (1024) array regions 102.

As shown in FIG. 1, the first microelectronic device structure 100 may include rows 108 of the array regions 102 extending in the Y-direction, and columns 110 of the array regions 102 extending in the X-direction. The rows 108 of the array regions 102 may, for example, include a first row including the first array region 102A and the third array region 102C, and a second row including the second array region 102B and the fourth array region 102D. The columns 110 of the array regions 102 may, for example, include a first column including the first array region 102A and the second array region 102B, and a second column including the third array region 102C and the fourth array region 102D.

With continued reference to FIG. 1, the WL exit regions 104 of the first microelectronic device structure 100 may include horizontal areas of the first microelectronic device structure 100 configured to contact with portions of WL structures (e.g., access line structures) within horizontal boundaries thereof. For an individual WL exit region 104, at least some WL structures operatively associated with the array regions 102 flanking (e.g., at opposing boundaries in the X-direction) the WL exit region 104 may have portions within the horizontal area of the WL exit region 104. In addition, the WL exit regions 104 may also be configured include conductive contact structures and conductive routing structures within the horizontal areas thereof that are operatively associated with the WL structures. As described in further detail below, some of the conductive contact structures within the WL exit regions 104 may couple the WL structures to control logic circuitry of additional control logic devices (e.g., sub-word line driver (SWD) devices) to subsequently be formed at least partially within the horizontal areas of the WL exit regions 104. As shown in FIG. 1, in some embodiments, the WL exit regions 104 horizontally extend in the X-direction, and are horizontally interposed between horizontally neighboring columns 110 of the array regions 102 in the Y-direction. The WL exit regions 104 may, for example, horizontally alternate with the columns 110 of the array regions 102 in the Y-direction.

As shown in FIG. 1, the first microelectronic device structure 100 may be formed to be free of (e.g., to not include) digit line (DL) exit regions (also referred to as “DL contact socket regions”) interposed between pairs of the array regions 102 horizontally neighboring one another in the X-direction. Accordingly, rows 108 of the array regions 102 horizontally neighboring one another in the X-direction may be relatively horizontally closer to one another than are columns 110 of the array regions 102 horizontally neighboring one another in the Y-direction.

With continued reference to FIG. 1, the peripheral regions 106 of the first microelectronic device structure 100 may comprise horizontal areas of the first microelectronic device structure 100 configured and positioned to facilitate electrical connections (e.g., by way of contact structures and routing structures formed within horizontal boundaries thereof) between subsequently formed control logic circuitry and additional structures (e.g., capacitor structures, BEOL structures), as described in further detail below. The peripheral regions 106 may horizontally neighbor one or more peripheral horizontal boundaries (e.g., in the Y-direction, in the X-direction) of one or more groups of the array regions 102. For clarity and case of understanding of the drawings and related description, FIG. 1 depicts the first microelectronic device structure 100 as being formed to include one (1) peripheral region 106 horizontally neighboring a shared horizontal boundary of the second array region 102B and the fourth array region 102D. However, the first microelectronic device structure 100 may be formed to include one or more of a different quantity and a different horizontal position of peripheral region(s) 106. As a non-limiting example, the peripheral region 106 may horizontally neighbor a shared horizontal boundary of a different group of the array regions 102 (e.g., a shared horizontal boundary of the third array region 102C and the fourth array region 102D, a shared horizontal boundary of the first array region 102A and the third array region 102C, a shared horizontal boundary of the first array region 102A and the second array region 102B). As another non-limiting example, the first microelectronic device structure 100 may be formed to include multiple (e.g., a plurality of, more than one) peripheral regions 106 horizontally neighboring different groups of the array regions 102 than one another. In some embodiments, multiple peripheral regions 106 collectively substantially horizontally surround (e.g., substantially horizontally circumscribe) the array regions 102.

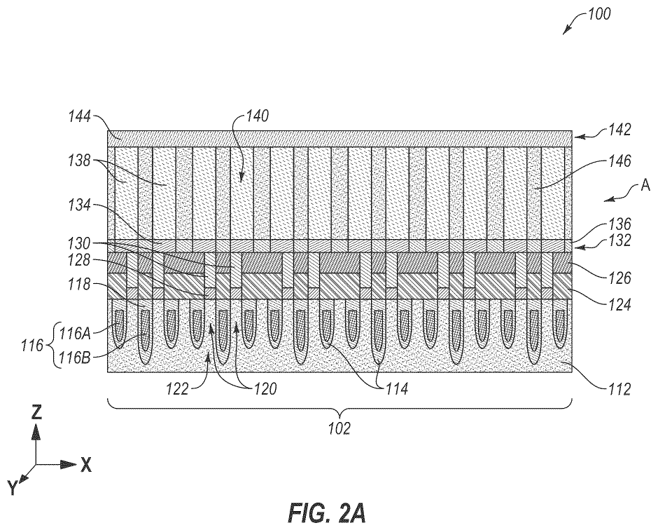

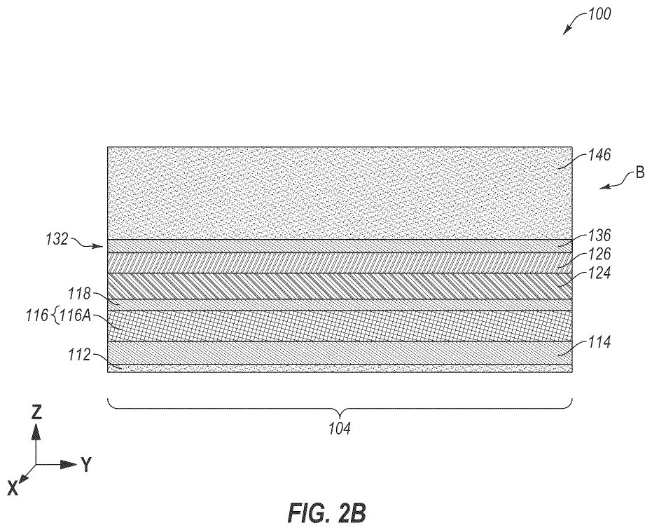

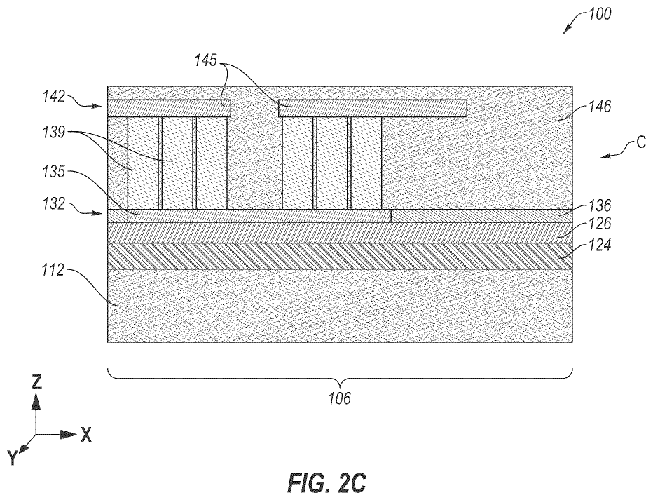

FIGS. 2A through 2C illustrate simplified, partial vertical cross-sectional views of different regions of the first microelectronic device structure 100 previously described with reference to FIG. 1. FIG. 2A illustrates a simplified, partial vertical cross-sectional view of one of the array regions 102 (e.g., the second array region 102B) of the first microelectronic device structure 100 about line A-A shown in FIG. 1. FIG. 2B illustrates a simplified, vertical cross-sectional view of one of the WL exit regions 104 of the first microelectronic device structure 100 about line B-B shown in FIG. 1. FIG. 2C illustrates a simplified, partial vertical cross-sectional view of one of the peripheral regions 106 of the first microelectronic device structure 100 about line C-C shown in FIG. 1.

Referring collectively to FIGS. 2A through 2C, the first microelectronic device structure 100 may be formed to include a first base semiconductor structure 112 including semiconductive pillar structures 120. Filled trenches may vertically extend into the first base semiconductor structure 112 and may horizontally neighbor the semiconductive pillar structures 120. The filled trenches may respectively include first isolation material 114, WL structures 116 (e.g., access line structures) partially surrounded by the first isolation material 114, and WL capping structures 118 overlying the WL structures 116.

The first base semiconductor structure 112 comprises a base material or construction upon which additional features (e.g., materials, structures, devices) of the first microelectronic device structure 100 are formed. The first base semiconductor structure 112 may comprise a semiconductor structure (e.g., a semiconductor wafer), or a base semiconductor material on a supporting structure. For example, the first base semiconductor structure 112 may comprise a conventional silicon substrate (e.g., a conventional silicon wafer), or another bulk substrate comprising a semiconductor material. In some embodiments, the first base semiconductor structure 112 comprises a silicon wafer. The first base semiconductor structure 112 may include one or more layers, structures, and/or regions formed therein and/or thereon.

The filled trenches of the first microelectronic device structure 100 may comprise trenches (e.g., openings, vias, apertures) within the first base semiconductor structure 112 that are at least partially (e.g., substantially) filled with the first isolation material 114, the WL structures 116, and the WL capping structures 118. Some of the filled trenches may vertically extend to and terminate at a different vertical position than some other of the filled trenches. For example, some of the filled trenches may be formed to be relatively vertically shallower than some other of the filled trenches. Some of the filled trenches may be employed as shallow trench isolation (STI) structures within the first base semiconductor structure 112.

The first isolation material 114 may be formed of and include at least one insulative material. By way of non-limiting example, the first isolation material 114 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the first isolation material 114 is formed of and includes SiOₓ (e.g., SiO₂). The first isolation material 114 may be substantially homogeneous, or the first isolation material 114 may be heterogeneous.

The WL structures 116 may horizontally extend in parallel in the Y-direction completely through the array region 102 (FIG. 2A) and at least partially through the WL exit region 104 (FIG. 2B). As used herein, the term “parallel” means substantially parallel. The WL structures 116 may include first WL structures 116A and second WL structures 116B, wherein the second WL structures 116B are employed as so-called “passing” WL structures. As shown in FIG. 2A, the second WL structures 116B may be positioned within the relatively deeper filled trenches, and may have relatively large vertical heights (e.g., in the Z-direction) than the first WL structures 116A. Tops (e.g., upper vertically boundaries) of the first WL structures 116A and second WL structures 116B may be substantially coplanar with one another; and bottoms (e.g., lower vertical boundaries) of the second WL structures 116B may vertically underlie (e.g., in the Z-direction) bottoms of the first WL structures 116B. At least some of the WL structures 116 may terminate within the WL exit region 104 (FIG. 2B). The side surfaces and a bottom surface of an individual WL structure 116 may be covered with the first isolation material 114, such that the first isolation material 114 is interposed between the first base semiconductor structure 112 and the WL structures 116. For example, portions of the first isolation material 114 may be horizontally interposed between the WL structures 116 and the semiconductive pillar structures 120 of the first base semiconductor structure 112. The WL structures 116 may individually be formed of and include conductive material. In some embodiments, the WL structures 116 are individually formed of and include one or more of W, Ru, Mo, and TiN_{y}.

The WL capping structures 118 may be formed on or over the WL structures 116. The WL capping structures 118 may at least partially (e.g., substantially) cover upper surfaces of the WL structures 116, and may horizontally neighbor the semiconductive pillar structures 120 of the first base semiconductor structure 112. WL capping structures 118 may individually be formed of and include at least one insulative material. In some embodiments, the WL capping structures 118 are individually formed of and include dielectric nitride material (e.g., SiN_{y}, such as Si₃N₄).

Within the array region 102 (FIG. 2A), the first microelectronic device structure 100 further includes access devices 122. The access devices 122 may individually include a channel region comprising a portion of a semiconductive pillar structure 120 of the first base semiconductor structure 112; a source region and a drain region respectively horizontally neighboring the channel region and individually comprising a conductively doped portion of the semiconductive pillar structure 120 of the first base semiconductor structure 112; at least one gate structure comprising a portion of at least one of the WL structures 116; and a gate dielectric structure comprising a portion of the first isolation material 114 interposed between the channel region thereof and the gate structure thereof.

With continued collective reference to FIGS. 2A through 2C, the first microelectronic device structure 100 may further include a first dielectric material 124 on or over the first base semiconductor structure 112, a second dielectric material 126 on or over of the first dielectric material 124, and a third dielectric material 136 on or over the second dielectric material 126. Within the array region 102 (FIG. 2A), the first dielectric material 124 may overlic the access devices 122 (FIG. 2A). The first dielectric material 124, the second dielectric material 126, and the third dielectric material 136 may individually be formed of and include insulative material. Material composition(s) of at least one of the first dielectric material 124, the second dielectric material 126, and the third dielectric material 136 may be different than material composition(s) of at least one other of the first dielectric material 124, the second dielectric material 126, and the third dielectric material 136. For example, the material composition of the second dielectric material 126 may be different than the material composition(s) of the first dielectric material 124 and the third dielectric material 136.

Within the array region 102 (FIG. 2A), the first microelectronic device structure 100 may further include first contact structures 128 over and in contact with portions of the semiconductive pillar structure 120 defining the channel regions of the access devices 122, and second contact structures 130 on or over the first contact structures 128. The first contact structures 128 and the second contact structures 130 may together (e.g., in combination) form so-called cell contact structures (also referred to herein as “CELLCON” structures) coupling the access devices 122 to first storage node devices 138, as described in further detail below. The first contact structures 128 and the second contact structures 130 may each be formed of and include conductive material. A material composition of the first contact structures 128 may be different than a material composition of the second contact structures 130. For example, the first contact structures 128 may individually be formed of and include conductive metal silicide material (e.g., cobalt silicide (CoSiₓ), tungsten silicide (WSiₓ), tantalum silicide (TaSiₓ), molybdenum silicide (MoSiₓ), nickel silicide (NiSiₓ), and titanium silicide (TiSiₓ)); and the second contact structures 130 may individually be formed of and include conductive metallic material (e.g., at least one elemental metal, such as one or more of W, Ti, Mo, Nb, V, Hf, Ta, Cr, Zr, Fc, Ru, Os, Co, Rh, Ir, Ni, Pd, Pt, Cu, Ag, Au, Al; at least one alloy, such as one or more of Co-based alloy, Fe-based alloy, Ni-based alloy, Fe- and Ni-based alloy, Co- and Ni-based alloy, Fe- and Co-based alloy, Co-and Ni- and Fe-based alloy, Al-based alloy, Cu-based alloy, magnesium (Mg)-based alloy, Ti-based alloy, steel, low-carbon steel, stainless steel).

Still referring to FIGS. 2A through 2C, a redistribution material (RDM) tier 132 (also referred to as “redistribution layer” (RDL) tier) may be formed to vertically overlie the second contact structures 130 (FIG. 2A) and the second dielectric material 126. The RDM tier 132 may vertically overlap and include portions of the third dielectric material 136. Within the array region 102 (FIG. 2A), the RDM tier 132 may include RDM structures 134 (also referred to as RDL structures) vertically extending through the third dielectric material 136 and in contact with the second contact structures 130. The RDM structures 134 may, for example, be employed to facilitate a horizontal arrangement (e.g., a hexagonal close packed arrangement) of the first storage node devices 138 that is different than a horizontal arrangement of the second contact structures 130 (and the first contact structures 128), while electrically connecting the second contact structures 130 to the first storage node devices 138. In addition, within the peripheral region 106 (FIG. 2C), the RDM tier 132 may include interconnect structures 135 vertically extending through the third dielectric material 136. The RDM structures 134 and the interconnect structures 135 may individually be formed of and include conductive material. In some embodiments, the RDM structures 134 and the interconnect structures 135 are individually formed of and include one or more of W, Ru, Mo, and TiN_{y}.

Referring to FIG. 2A, the first storage node devices 138 (e.g., first capacitors) may be formed on or over the RDM structures 134 of the RDM tier 132. The first storage node devices 138 may be in electrical contact with the RDM structures 134, and, hence with the second contact structures 130, the first contact structures 128, and the access devices 122. The first storage node devices 138 may be coupled to the access devices 122 by way of the first contact structures 128, the second contact structures 130, and the RDM structures 134 to form memory cells 140 (e.g., DRAM cells) within the array region 102. Each memory cell 140 may individually include one of the access devices 122, one of the first storage node devices 138, one of the first contact structures 128, one of the second contact structures 130, and one of the RDM structures 134. The first storage node devices 138 may individually be formed and configured to store a charge representative of a programmable logic state of the memory cell 140 including the first storage node device 138. In some embodiments, the first storage node devices 138 are capacitors. During use and operation, a charged capacitor may represent a first logic state, such as a logic 1; and an uncharged capacitor may represent a second logic state, such as a logic 0. Each of the first storage node devices 138 may, for example, be formed to include a first electrode (e.g., a bottom electrode), a second electrode (e.g., a top electrode), and a dielectric material between the first electrode and the second electrode.

Referring to FIG. 2C, within the peripheral region 106, one or more groups of second storage node devices 139 (e.g., second capacitors) may, optionally, also be formed. If formed within the peripheral region 106, the second storage node devices 139 may be coupled to at least some of the interconnect structures 135 positioned within the peripheral region 106. If formed, the second storage node devices 139 may be employed to enhance the performance of a microelectronic device formed through the methods of the disclosure. The second storage node devices 139 may, for example, subsequently (e.g., following completion of additional processing stages of the method of forming the microelectronic device) be coupled to and employed to power additional devices (e.g., control logic devices) of the microelectronic device. In some embodiments, the second storage node devices 139 are subsequently coupled to and employed to power control logic devices comprising complementary metal-oxide-semiconductor (CMOS) circuitry. As described in further detail below, the control logic devices may be components of an additional, separately formed microelectronic device structure that is subsequently attached to the first microelectronic device structure 100 to facilitate the formation of a microelectronic device of the disclosure.

Referring collectively to FIGS. 2A and 2C, a first routing tier 142 may be formed over the first storage node devices 138 (FIG. 2A) and the second storage node devices 139 (FIG. 2C) (if any). Within the array region 102 (FIG. 2A), the first routing tier 142 may include first routing structures 144 horizontally extending between and coupling at least some of the first storage node devices 138 (and, hence, at least some of the memory cells 140) within the array region 102. Within the peripheral region 106 (FIG. 2C), the first routing tier 142 may include first additional routing structures 145 horizontally extending between and coupling at least some of the second storage node devices 139 within the peripheral region 106. The first routing structures 144 and the first additional routing structures 145 may individually formed of and include conductive material.

With reference to FIGS. 2A through 2C, a second isolation material 146 may be formed on or over portions of at least the third dielectric material 136 (FIGS. 2A through 2C), the RDM structures 134 (FIG. 2A), the interconnect structures 135 (FIG. 2C), the first storage node devices 138 (FIG. 2A), the second storage node devices 139 (FIG. 2C), the first routing structures 144 (FIG. 2A), and the first additional routing structures 145 (FIG. 2C). The second isolation material 146 may be formed of and include at least one insulative material. In some embodiments, the second isolation material 146 is formed of and includes dielectric oxide material, such as SiOₓ (e.g., SiO₂). The second isolation material 146 may be substantially homogeneous, or the second isolation material 146 may be heterogeneous. An upper surface of the second isolation material 146 may be formed to be substantially planar, and may vertically overlie upper surfaces of the first routing structures 144 (FIG. 2A) and the first additional routing structures 145 (FIG. 2C) of the first routing tier 142 (FIGS. 2A and 2C).

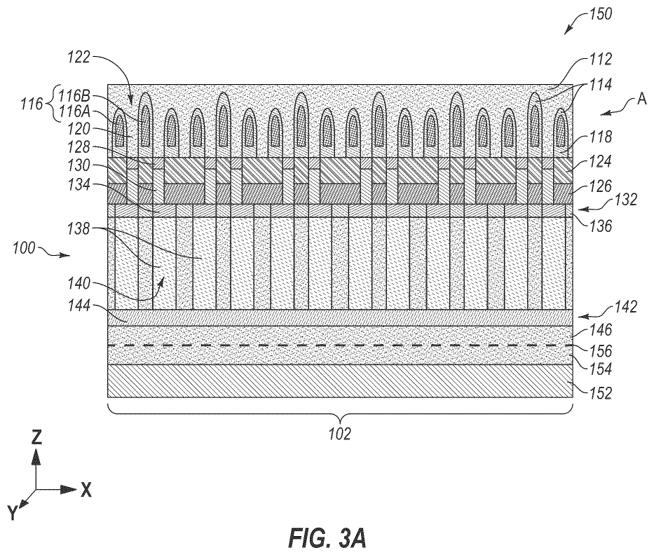

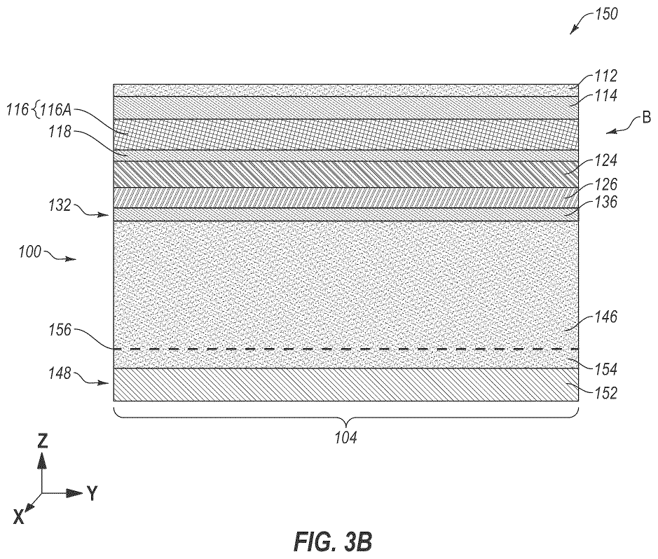

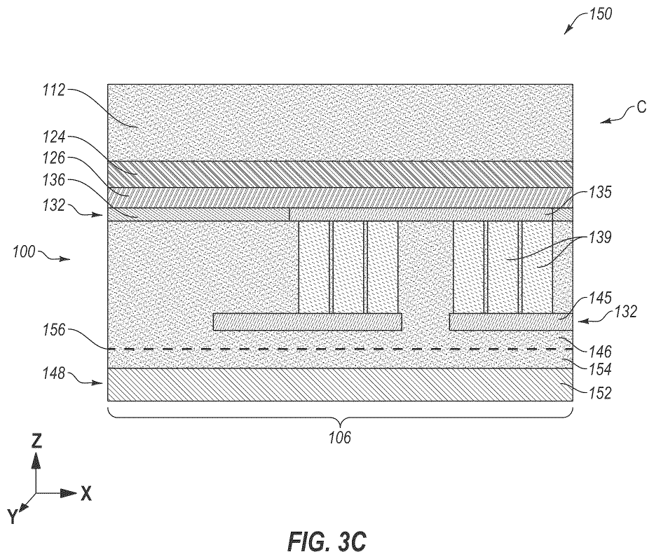

FIGS. 3A through 3C are simplified, partial vertical cross-sectional views of the array region 102 (FIG. 3A), the WL exit region 104 (FIG. 3B), and the peripheral region 106 (FIG. 3C) at another processing stage of the method of forming the microelectronic device following the processing stage processing stage previously described with reference to FIGS. 2A through 2C. FIG. 3A shows a simplified, partial vertical cross-sectional view of the array region 102 about line A-A shown in FIG. 1 following the processing previously described with reference to FIGS. 2A through 2C. FIG. 3B shows a simplified, partial vertical cross-sectional view of the WL exit region 104 about line B-B shown in FIG. 1 following the processing previously described with reference to FIGS. 2A through 2C. FIG. 3C shows a simplified, partial vertical cross-sectional view of the peripheral region 106 about line C-C shown in FIG. 1 following the processing previously described with reference to FIGS. 2A through 2C.

As collectively depicted in FIGS. 3A through 3C, a carrier structure 148 (e.g., a carrier wafer) including a base structure 152 and a third isolation material 154 on or over the base structure 152 may be attached (e.g., bonded) to the second isolation material 146 to form a first assembly 150, and then the first assembly 150 may be vertically inverted (e.g., flipped upside down in the Z-direction). Following vertical inversion of the first assembly 150, the first base semiconductor structure 112 may be positioned relatively vertically higher (e.g., in the Z-direction) than the base structure 152.

Referring collectively to FIGS. 3A through 3C, the base structure 152 of the carrier structure 148 includes a base material or construction upon which additional features (e.g., materials, structures, devices) of the formed. In some embodiments, the base structure 152 comprises a wafer. The base structure 152 may be formed of and include one or more of semiconductor material, a base semiconductor material on a supporting structure, glass material (e.g., one or more of borosilicate glass (BSP), phosphosilicate glass (PSG), fluorosilicate glass (FSG), borophosphosilicate glass (BPSG), aluminosilicate glass, an alkaline carth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). By way of non-limiting example, the base structure 152 may comprise a semiconductor wafer (e.g., a silicon wafer), a glass wafer, or a ceramic wafer. The base structure 152 may include one or more layers, structures, and/or regions formed therein and/or thereon.

The third isolation material 154 of the carrier structure 148 may be formed of and include at least one insulative material. A material composition of the third isolation material 154 may be substantially the same as a material composition of the second isolation material 146; or the material composition of the third isolation material 154 may be different than the material composition of the second isolation material 146. In some embodiments, the third isolation material 154 is formed of and includes a dielectric oxide material, such as SiOₓ (e.g., SiO₂). The third isolation material 154 may be substantially homogeneous, or the third isolation material 154 may be heterogeneous.

To attach the third isolation material 154 of the carrier structure 148 to the second isolation material 146, the carrier structure 148 may be vertically inverted (e.g., flipped upside down in the Z-direction), the third isolation material 154 thereof may be provided in physical contact with the second isolation material 146 at a first interface 156, and the third isolation material 154 and the second isolation material 146 may be exposed to annealing conditions to form bonds (e.g., oxide-to-oxide bonds) between the third isolation material 154 and the second isolation material 146. By way of non-limiting example, the third isolation material 154 and the second isolation material 146 may be exposed to a temperature greater than or equal to about 400° C. (e.g., within a range of from about 400° C. to about 800° C., greater than about 800° C.) to form oxide-to-oxide bonds between the second isolation material 146 and the third isolation material 154. In some embodiments, the second isolation material 146 and the third isolation material 154 are exposed to at least one temperature greater than about 800° C. to form oxide-to-oxide bonds between the second isolation material 146 and the third isolation material 154. In FIGS. 3A through 3C, the third isolation material 154 and the second isolation material 146 are distinguished from one another by way of a dashed line representing the first interface 156 therebetween prior to bonding. However, the third isolation material 154 and the second isolation material 146 may be integral and continuous with one another following the bonding process. The third isolation material 154 may be attached to the second isolation material 146 without a bond line.

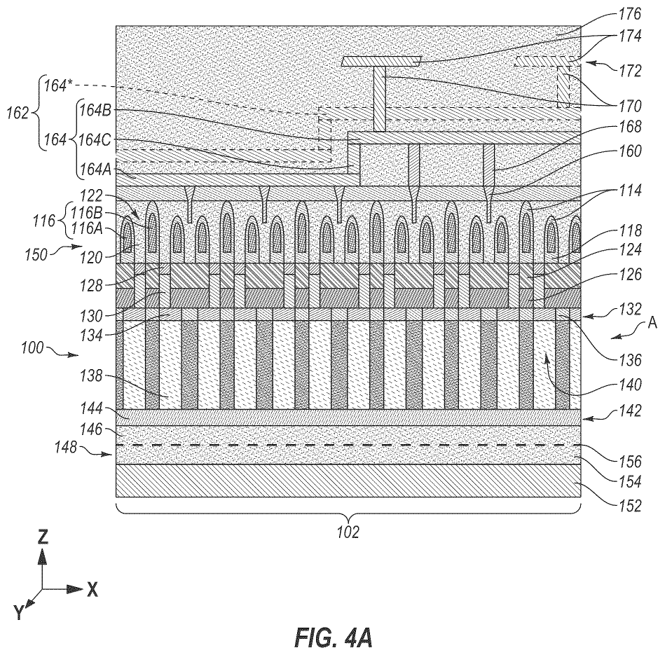

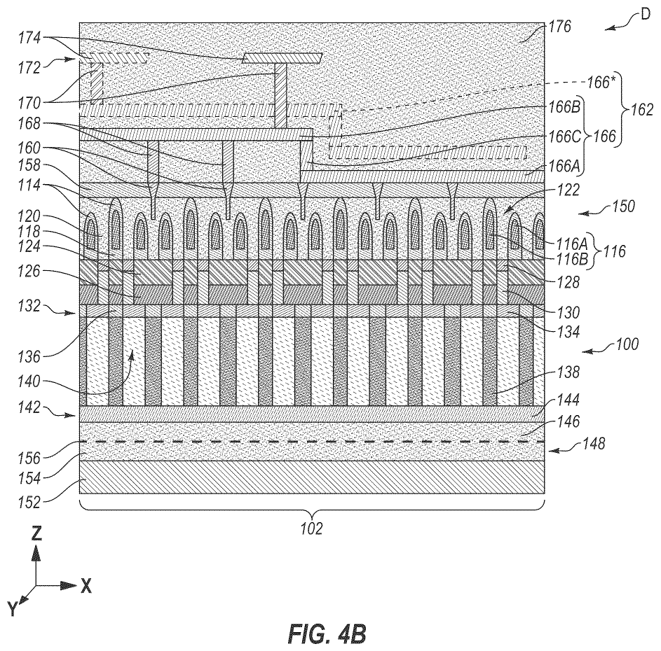

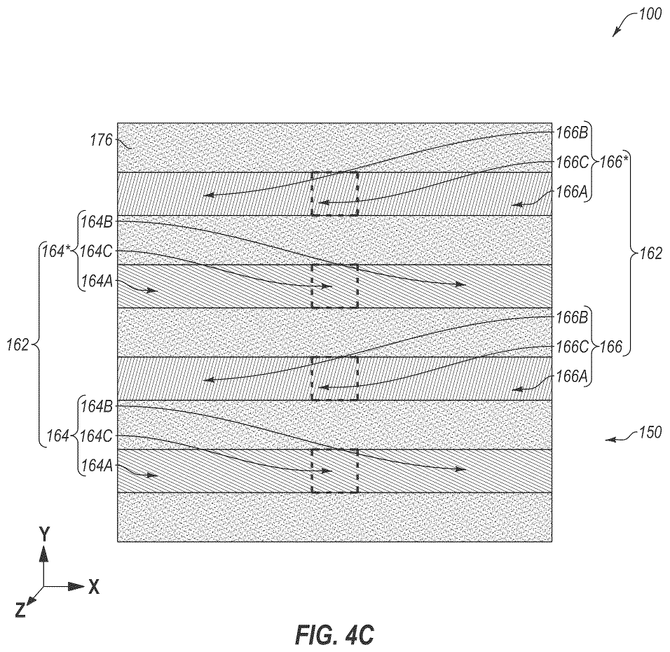

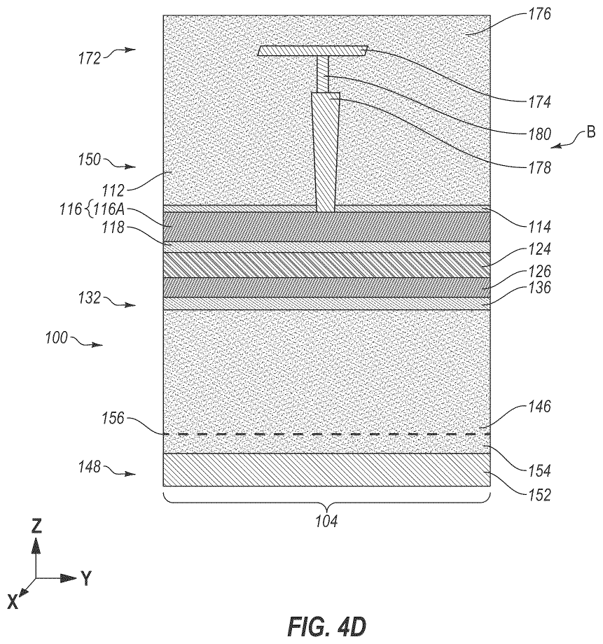

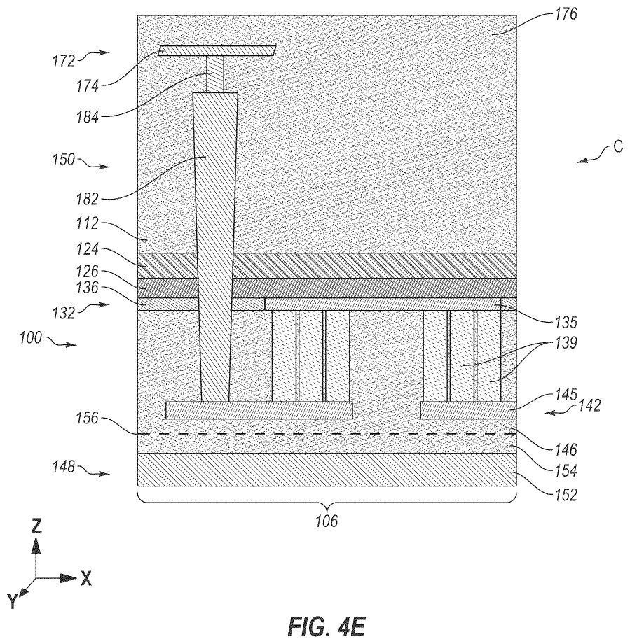

FIGS. 4A through 4E are simplified, partial vertical cross-sectional views (FIGS. 4A, 4B, 4D, and 4E) and a simplified, partial top-down view (FIG. 4C) of the array region 102 (FIGS. 4A through 4C), the WL exit region 104 (FIG. 4D), and the peripheral region 106 (FIG. 4E) at another processing stage of the method of forming the microelectronic device following the processing stage previously described with reference to FIGS. 3A through 3C. FIG. 4A shows a simplified, partial vertical cross-sectional view of the array region 102 about line A-A shown in FIG. 1 following the processing previously described with reference to FIGS. 3A through 3C. FIG. 4B shows a simplified, partial vertical cross-sectional view of the array region 102 about line D-D shown in FIG. 1 following the processing previously described with reference to FIGS. 3A through 3C. FIG. 4C shows a simplified, partial top-down view of the array region 102 about dashed box E shown in FIG. 1 following the processing previously described with reference to FIGS. 3A through 3C. FIG. 4D shows a simplified, partial vertical cross-sectional view of the WL exit region 104 about line B-B shown in FIG. 1 following the processing previously described with reference to FIGS. 3A through 3C. FIG. 4E shows a simplified, partial vertical cross-sectional view of the peripheral region 106 about line C-C shown in FIG. 1 following the processing previously described with reference to FIGS. 3A through 3C.

Referring collectively to FIGS. 4A and 4B, within the array region 102, a vertical thickness (e.g., in the Z-direction) of at least the first base semiconductor structure 112 may be thinned (e.g., reduced), a fourth insulative material 158 may be formed on or over the semiconductive pillar structures 120, and then first DL contact structures 160 (e.g., first bit line contact structures) may be formed to vertically extend through the fourth insulative material 158 and to or into the semiconductive pillar structures 120. The first DL contact structures 160 may be formed to contact (e.g., physically contact, electrically contact) portions of the semiconductive pillar structures 120 defining source/drain regions of the access devices 122. The first DL contact structures 160 may be considered to contact back sides of the semiconductive pillar structures 120, while the cell contact structures individually including a combination of a first contact structure 128 and a second contact structure 130 may be considered to contact front sides of the semiconductive pillar structures 120 opposing the back sides.

The first base semiconductor structure 112 may be thinned to a desired vertical thickness, such as a vertical thickness within a range of from about 200 nanometers (nm) to about 2000 nm. In some embodiments, the first base semiconductor structure 112 is vertically thinned to vertical boundaries of the relatively vertically deeper filled trenches having the second WL structures 116B therein. In additional embodiments, the first base semiconductor structure 112 is vertically thinned to a greater extent, such that portions of the first isolation material 114 and the second WL structures 116B within the relatively vertically deeper filled trenches are also removed.

The fourth insulative material 158 of may be formed of and include at least one insulative material. In some embodiments, the fourth insulative material 158 is formed of and includes a dielectric oxide material, such as SiOₓ (e.g., SiO₂). The fourth insulative material 158 may be substantially homogeneous, or the fourth insulative material 158 may be heterogeneous.

As shown in FIGS. 4A and 4B, the first DL contact structures 160 may be horizontally offset from the first contact structure 128 and a second contact structure 130 since the source/drain regions of the access devices 122 are horizontally offset form the channel regions of the access devices 122. In some embodiments, lower portions of the first DL contact structures 160 vertically extend into the semiconductive pillar structures 120, and upper portions of the first DL contact structures 160 vertically overlie the semiconductive pillar structures 120. The lower portion of an individual first digit line contact structure 160 may have relatively smaller horizontal dimensions than the upper portion of an individual first digit line contact structure 160. In some embodiments, the upper portion of individual first digit line contact structure 160 tapers from relatively greater horizontal areas relatively more distal from the lower portion (and, hence, the semiconductive pillar structures 120) to relatively smaller horizontal areas relatively more proximate to the lower portion. In addition, upper surfaces of the first digit line contact structure 160 may be substantially coplanar with an upper surface of the fourth insulative material 158. The first DL contact structures 160 may individually be formed of and include conductive material, and may respectively be substantially homogeneous or heterogeneous. In some embodiments, the first DL contact structures 160 are individually formed of and include one or more of W, Ru, Mo, and TiN_{y}.

Still referring to FIGS. 4A and 4B, hieratical digit line (HDL) structures 162 may be formed over and in contact (e.g., physical contact, electrical contact) with the first DL contact structures 160. The HDL structures 162 may horizontally extend in parallel with one another in the X-direction, and may individually be formed of and include conductive material. In some embodiments, the HDL structures 162 are individually formed of and include one or more of W, Ru, Mo, and TiN_{y}.

The HDL structures 162 may include first base HDL structures 164 (FIG. 4A) (e.g., odd base HDL structures), first complementary HDL structures 164* (FIG. 4A) (e.g., odd complementary HDL structures), second base HDL structures 166 (FIG. 4B) (e.g., even base HDL structures), and second complementary HDL structures 166* (FIG. 4B) (e.g., even complementary HDL structures). The first base HDL structures 164 (FIG. 4A) and the first complementary HDL structures 164* (FIG. 4A) are collectively referred to herein as first HDL structures 164, 164* (e.g., odd HDL structures). The second base HDL structures 166 (FIG. 4B) and the second complementary HDL structures 166* (FIG. 4B) are collectively referred to herein as second HDL structures 166, 166* (e.g., even HDL structures).

Referring to FIG. 4C, the first HDL structures 164, 164* horizontally alternate with the second HDL structures 166, 166* in the Y-direction. For example, as shown in FIG. 4C, the HDL structures 162 may be formed to include a sequence (e.g., repeating sequence), in the Y-direction, of a first base HDL structure 164, a second base HDL structure 166, a first complementary HDL structure 164*, and a second complementary HDL structure 166*. For example, an individual second base HDL structure 166 may be horizontally interposed, in the Y-direction, between an individual first base HDL structure 164 and an individual first complementary HDL structure 164* horizontally neighboring the first base HDL structure 164 in the Y-direction. As another example, an individual first complementary HDL structure 164* may be horizontally interposed, in the Y-direction, between an individual second base HDL structure 166 and an individual second complementary HDL structure 166* horizontally neighboring the second base HDL structure 166 in the Y-direction. In FIG. 4C, some features of the first assembly 150 (FIGS. 4A and 4B) at the processing stage of FIGS. 4A through 4E, such as features vertically offset from (e.g., vertically overlying, vertically underlying) the HDL structures 162 are not depicted for clarity and ease of understanding the drawings and related description. Configurations of the HDL structures 162, including configurations of the first HDL structures 164, 164* and configurations of the second HDL structures 166, 166*, are described in further detail below.

Referring to collectively to FIGS. 4A and 4C, geometric configurations (e.g., shapes, dimensions) of the first base HDL structures 164 be may substantially the same as geometric configurations (e.g., shapes, dimensions) of the first complementary HDL structures 164*. The first base HDL structures 164 may be horizontally offset from the first complementary HDL structures 164* in the Y-direction, and the first base HDL structures 164 may horizontally extend in parallel with the first complementary HDL structures 164* in the X-direction. The first base HDL structures 164 may horizontally alternate with the first complementary HDL structures 164* in the Y-direction, such that an individual first base HDL structure 164 is horizontally interposed in the Y-direction between two (2) first complementary HDL structures 164*, and/or such that an individual first complementary HDL structure 164* is horizontally interposed in the Y-direction between two (2) first base HDL structures 164. In FIG. 4A, the first complementary HDL structure 164* is depicted by way of dashed lines to represent that it is outside of (e.g., horizontally offset in the Y-direction from) the vertical plane (e.g., XZ-plane) of the first base HDL structure 164. The first complementary HDL structure 164* is within a different vertical plane (e.g., a different XZ-plane) than the first base HDL structure 164, wherein the vertical plane intersecting the first base HDL structure 164 is about line A-A shown in FIG. 1. In addition, the first complementary HDL structures 164* may be substantially vertically aligned (e.g., in the Z-direction) with the first base HDL structures 164. Portions of the first complementary HDL structures 164* at substantially the same horizontal positions in the X-direction as portions of the first base HDL structures 164 may substantially vertically overlap the portions of the first base HDL structures 164 in the Z-direction. In this regard, while in FIG. 4A the first complementary HDL structure 164* is depicted as vertically overlying the first base HDL structure 164 for ease of understanding the drawings and related description, it will be understood that the first complementary HDL structure 164* does not vertically overlie the first base HDL structure 164, but is substantially vertically aligned with the first base HDL structure 164. Namely, the first HDL structures 164, 164* may be substantially vertically aligned with one another within the array region 102. In addition, while for case of understanding the drawings and related description corresponding (e.g., similarly shaped and sized) portions the first complementary HDL structure 164* and the first base HDL structure 164 are shown in FIG. 4A as being horizontally offset from one another in the X-direction, it will be understood that the corresponding portions of the first complementary HDL structure 164* and the first base HDL structure 164 may horizontally overlap (e.g., may be substantially horizontally aligned with) one another in the X-direction.

Each of the first HDL structures 164, 164* (e.g., each of the first base HDL structures 164 and each of the first complementary HDL structures 164*) may be formed to include a lower section 164A, an upper section 164B, and a middle section 164C. The upper section 164B may vertically overlie the lower section 164A in the Z-direction, may be substantially horizontally aligned with the lower section 164A in the Y-direction, and may only partially overlap the lower section 164A in the X-direction. A sub-section of the lower section 164A located proximate an end (e.g., boundary) of the lower section 164A in the X-direction may horizontally overlap, in the X-direction, a sub-section of the upper section 164B located proximate an end (e.g., boundary) of the upper section 164B in the X-direction. Additional sub-sections of the lower section 164A located relatively more distal from the end of the lower section 164A in the X-direction may be completely horizontally offset, in the X-direction, from additional sub-sections of the upper section 164B located relatively more distal from the end of the upper section 164B in the X-direction. In addition, the middle section 164C may vertically extend in the Z-direction from and between the lower section 164A and the upper section 164B. The middle section 164C may be substantially horizontally aligned with the lower section 164A and the upper section 164B in the Y-direction, and may be substantially confined with a horizontal area of sub-sections of the lower section 164A and the upper section 164B horizontally overlapping one another in the X-direction. Lower sections 164A of first HDL structures 164, 164* horizontally neighboring one another in the Y-direction (e.g., a first base HDL structure 164 and a horizontally neighboring first complementary HDL structure 164*) may horizontally overlap one another in the X-direction and may vertically overlap one another in the Z-direction. Upper sections 164B of first HDL structures 164, 164* horizontally neighboring one another in the Y-direction may horizontally overlap one another in the X-direction and may vertically overlap one another in the Z-direction. Middle sections 164C of first HDL structures 164, 164* horizontally neighboring one another in the Y-direction may horizontally overlap one another in the X-direction and may vertically overlap one another in the Z-direction.

Referring collectively to FIGS. 4B and 4C, geometric configurations (e.g., shapes, dimensions) of the second base HDL structures 166 be may substantially the same as geometric configurations (e.g., shapes, dimensions) of the second complementary HDL structures 166*. The second base HDL structures 166 may be horizontally offset from the second complementary HDL structures 166* in the Y-direction, and the second base HDL structures 166 may horizontally extend in parallel with the second complementary HDL structures 166* in the X-direction. The second base HDL structures 166 may horizontally alternate with the second complementary HDL structures 166* in the Y-direction, such that an individual second base HDL structure 166 is horizontally interposed in the Y-direction between two (2) second complementary HDL structures 166*, and/or such that an individual second complementary HDL structure 166* is horizontally interposed in the Y-direction between two (2) second base HDL structures 166. In FIG. 4B, the second complementary HDL structure 166* is depicted by way of dashed lines to represent that it is outside of (e.g., horizontally offset in the Y-direction from) the vertical plane (e.g., XZ-plane) of the second base HDL structure 166. The second complementary HDL structure 166* is within a different vertical plane (e.g., a different XZ-plane) than the second base HDL structure 166, wherein the vertical plane intersecting the second base HDL structure 166 is about line D-D shown in FIG. 1. In addition, the second complementary HDL structures 166* may be substantially vertically aligned (e.g., in the Z-direction) with the second base HDL structures 166. Portions of the second complementary HDL structures 166* at substantially the same horizontal positions in the X-direction as portions of the second base HDL structures 166 may substantially vertically overlap the portions of the second base HDL structures 166 in the Z-direction. In this regard, while in FIG. 4B the second complementary HDL structure 166* is depicted as vertically overlying the second base HDL structure 166 for ease of understanding the drawings and related description, it will be understood that the second complementary HDL structure 166* does not vertically overlie the second base HDL structure 166, but is substantially vertically aligned with the second base HDL structure 166. Namely, the second HDL structures 166, 166* may be substantially vertically aligned with one another within the array region 102. In addition, while for case of understanding the drawings and related description corresponding (e.g., similarly shaped and sized) portions the second complementary HDL structure 166* and the second base HDL structure 166 are shown in FIG. 4B as being horizontally offset from one another in the X-direction, it will be understood that the corresponding portions of the second complementary HDL structure 166* and the second base HDL structure 166 may horizontally overlap (e.g., may be substantially horizontally aligned with) one another in the X-direction.

Each of the second HDL structures 166, 166* (e.g., each of the second base HDL structures 166 and each of the second complementary HDL structures 166*) may be formed to include an additional lower section 166A, an additional upper section 166B, and an additional middle section 166C. The additional upper section 166B may vertically overlie the additional lower section 166A in the Z-direction, may be substantially horizontally aligned with the additional lower section 166A in the Y-direction, and may only partially overlap the additional lower section 166A in the X-direction. A sub-section of the additional lower section 166A located proximate an end (e.g., boundary) of the additional lower section 166A in the X-direction may horizontally overlap, in the X-direction, a sub-section of the additional upper section 166B located proximate an end (e.g., boundary) of the additional upper section 166B in the X-direction. Further sub-sections of the additional lower section 166A located relatively more distal from the end of the additional lower section 166A in the X-direction may be completely horizontally offset, in the X-direction, from further sub-sections of the additional upper section 166B located relatively more distal from the end of the additional upper section 166B in the X-direction. In addition, the additional middle section 166C may vertically extend in the Z-direction from and between the additional lower section 166A and the additional upper section 166B. The additional middle section 166C may be substantially horizontally aligned with the additional lower section 166A and the additional upper section 166B in the Y-direction, and may be substantially confined with a horizontal arca of sub-sections of the additional lower section 166A and the additional upper section 166B horizontally overlapping one another in the X-direction. Additional lower sections 166A of second HDL structures 166, 166* horizontally neighboring one another in the Y-direction (e.g., a second base HDL structure 166 and a horizontally neighboring second complementary HDL structure 166*) may horizontally overlap one another in the X-direction and may vertically overlap one another in the Z-direction. Additional upper sections 166B of second HDL structures 166, 166* horizontally neighboring one another in the Y-direction may horizontally overlap one another in the X-direction and may vertically overlap one another in the Z-direction. Additional middle sections 166C of second HDL structures 166, 166* horizontally neighboring one another in the Y-direction may horizontally overlap one another in the X-direction and may vertically overlap one another in the Z-direction.

Referring collectively to FIGS. 4A through 4C, the lower sections 164A of the first HDL structures 164, 164* may vertically overlap (e.g., may be substantially vertically aligned with) the additional lower sections 166A of the second HDL structures 166, 166*, and may be horizontally offset from the additional lower sections 166A of the second HDL structures 166, 166* in each of the Y-direction and the X-direction. The lower sections 164A of the first HDL structures 164, 164* may only partially horizontally overlap the additional lower sections 166A of the second HDL structures 166, 166* in the X-direction, if at all. In addition, the upper sections 164B of the first HDL structures 164, 164* may vertically overlap (e.g., may be substantially vertically aligned with) the additional upper sections 166B of the second HDL structures 166, 166*, and may be horizontally offset from the additional upper sections 166B of the second HDL structures 166, 166* in each of the Y-direction and the X-direction. The upper sections 164B of the first HDL structures 164, 164* may only partially horizontally overlap the additional upper sections 166B of the second HDL structures 166, 166* in the X-direction, if at all. The lower sections 164A of the first HDL structures 164, 164* may horizontally overlap the additional upper sections 166B of the second HDL structures 166, 166* in the X-direction, and may vertically underlie the additional upper sections 166B of the second HDL structures 166, 166* in the Z-direction. Similarly, the upper sections 164B of the first HDL structures 164, 164* may horizontally overlap the additional lower sections 166A of the second HDL structures 166, 166* in the X-direction, and may vertically overlie the additional lower sections 166A of the second HDL structures 166, 166* in the Z-direction. Accordingly, the first HDL structures 164, 164* may be considered to be vertically inverted (e.g., vertically flipped, vertically twisted) relative to the second HDL structures 166, 166*. Vertically inverting the first HDL structures 164, 164* relative to the second HDL structures 166, 166* may mitigate undesirable parasitic capacitance between the first HDL structures 164, 164* and the second HDL structures 166, 166*.

Still referring collectively to FIGS. 4A through 4C, the middle sections 164C of the first HDL structures 164, 164* may vertically overlap (e.g., may be substantially vertically aligned with) the additional middle sections 166C of the second HDL structures 166, 166*, and may be horizontally offset from the additional middle sections 166C of the second HDL structures 166, 166* in at least the Y-direction. The middle sections 164C of the first HDL structures 164, 164* may horizontally overlap (e.g., only partially horizontally overlap, substantially horizontally overlap) the additional middle sections 166C of the second HDL structures 166, 166* in the X-direction, or may be substantially horizontally offset from the additional middle sections 166C of the second HDL structures 166, 166* in the X-direction.

Referring collectively to FIGS. 4A and 4B, the lower sections 164A of the first HDL structures 164, 164* and the additional lower sections 166A of the second HDL structures 166, 166* respectively contact some of the first DL contact structures 160. In some embodiments, the lower sections 164A of the first HDL structures 164, 164* and the additional lower sections 166A of the second HDL structures 166, 166* respectively directly physically contact some of the first DL contact structures 160. In addition, second DL contact structures 168 may be formed to vertically extend from some other of the first DL contact structures 160 to the upper sections 164B of the first HDL structures 164, 164* and the additional upper sections 166B of the second HDL structures 166, 166*. The second DL contact structures 168 may individually be formed of and include conductive material. In some embodiments, the second DL contact structures 168 are individually formed of and include one or more of W, Ru, Mo, and TiN_{y}.

Third DL contact structures 170 may be formed on or over the upper sections 164B of the first HDL structures 164, 164* and the additional upper sections 166B of the second HDL structures 166, 166*. Each of the upper sections 164B of the first HDL structures 164, 164* and each of the additional upper sections 166B of the second HDL structures 166, 166* may have at least one of the third DL contact structures 170 in contact (e.g., physical contact, electrical contact) therewith. The third DL contact structures 170 may individually be formed of and include conductive material. In some embodiments, the third DL contact structures 170 are individually formed of and include one or more of W, Ru, Mo, and TiN_{y}.

Referring next to FIG. 4D, within the WL exit regions 104, first WL contact structures 178 may be formed on or over the WL structures 116. Each of the WL structures 116 may have at least one of the first WL contact structures 178 in contact (e.g., physical contact, electrical contact) therewith. In addition, second WL contact structures 180 may be formed on or over the first WL contact structures 178. Each of the first WL contact structures 178 may have at least one of the second WL contact structures 180 in contact (e.g., physical contact, electrical contact) therewith. The first WL contact structures 178 and the second WL contact structures 180 may individually be formed of and include conductive material. In some embodiments, the first WL contact structures 178 and the second WL contact structures 180 are individually formed of and include one or more of W, Ru, Mo, and TiN_{y}.

Referring next to FIG. 4E, within the peripheral regions 106, third contact structures 182 may be formed on or over at least some of the first additional routing structures 145 within the first routing tier 142. One or more of the first additional routing structures 145 within an individual peripheral region 106 may have one or more of the third contact structures 182 in contact (e.g., physical contact, electrical contact) therewith. In addition, fourth contact structures 184 may be formed on or over the third contact structures 182. Each of the third contact structures 182 may have at least one of the fourth contact structures 184 in contact (e.g., physical contact, electrical contact) therewith. The third contact structures 182 and the fourth contact structures 184 may individually be formed of and include conductive material. In some embodiments, the third contact structures 182 and the fourth contact structures 184 are individually formed of and include one or more of W, Ru, Mo, and TiN_{y}.

Referring collectively to FIGS. 4A, 4B, 4D, and 4E, a second routing tier 172 including second routing structures 174 may be formed over the HDL structures 162 (FIGS. 4A and 4B). Within the array regions 102 (FIGS. 4A and 4B), some of the second routing structures 174 may be formed in contact (e.g., physical contact, electrical contact) with the third DL contact structures 170. Within the WL exit regions 104 (FIG. 4D), others of the second routing structures 174 may be formed in contact (e.g., physical contact, electrical contact) with the second WL contact structures 180. Within the peripheral regions 106 (FIG. 4E), yet others of the second routing structures 174 may be formed in contact (e.g., physical contact, electrical contact) with the fourth contact structures 184. The second routing structures 174 of the second routing tier 172 may individually formed of and include conductive material. In some embodiments, the second routing structures 174 are individually formed of and include one or more of W, Ru, Mo, and TiN_{y}.

With collective reference to FIGS. 4A through 4E, a fourth isolation material 176 may be formed on or over portions of the HDL structures 162 (FIGS. 4A through 4C), the second DL contact structures 168 (FIGS. 4A and 4B), the third DL contact structures 170 (FIGS. 4A and 4B), the first WL contact structures 178 (FIG. 4D), the second WL contact structures 180 (FIG. 4D), the third contact structures 182 (FIG. 4E), the fourth contact structures 184 (FIG. 4E), and the second routing structures 174 (FIGS. 4A, 4B, 4D, and 4E) of the second routing tier 172 (FIGS. 4A, 4B, 4D, and 4E). The fourth isolation material 176 may be formed of and include at least one insulative material. In some embodiments, the fourth isolation material 176 is formed of and includes dielectric oxide material, such as SiOₓ (e.g., SiO₂). The fourth isolation material 176 may be substantially homogeneous, or the fourth isolation material 176 may be heterogeneous. An upper surface of the fourth isolation material 176 may be formed to be substantially planar, and may vertically overlie upper surfaces of the second routing structures 174 (FIGS. 4A, 4B, 4D, and 4E) of the second routing tier 172 (FIGS. 4A, 4B, 4D, and 4E).

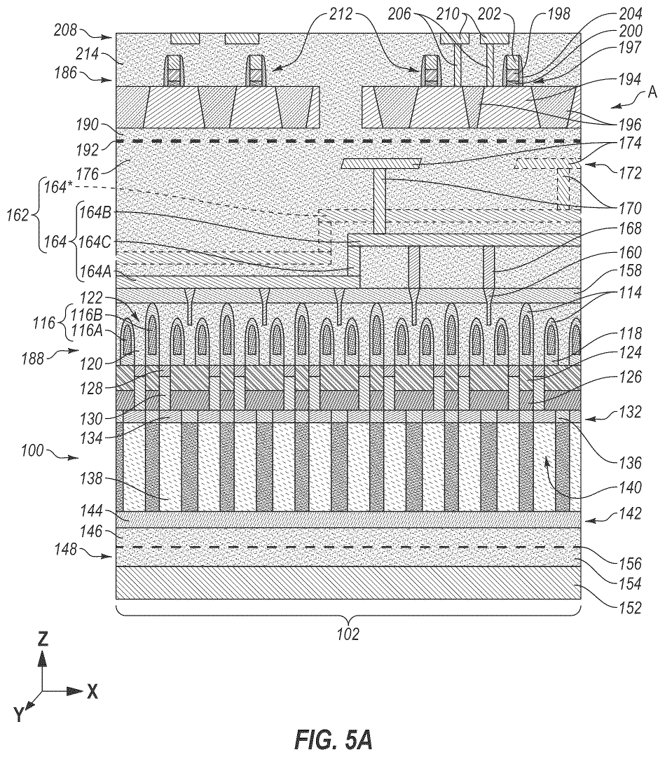

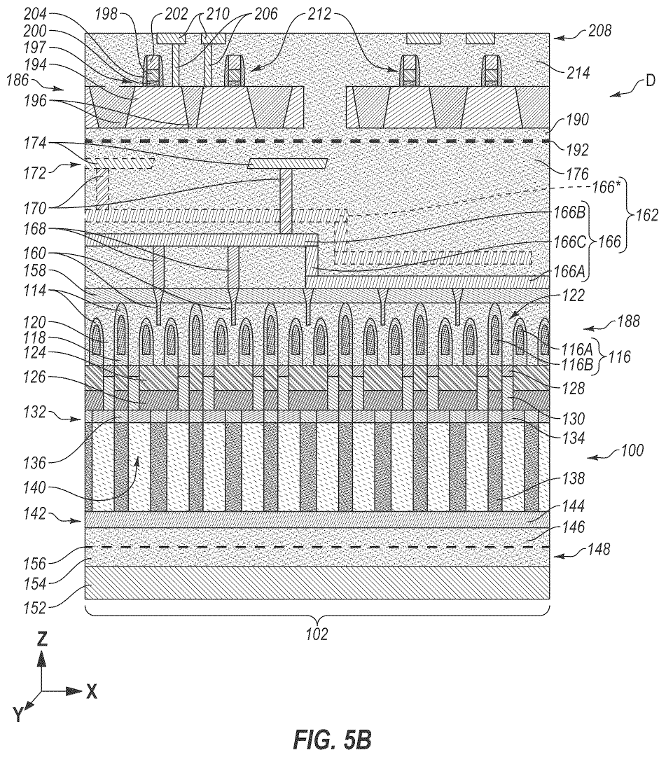

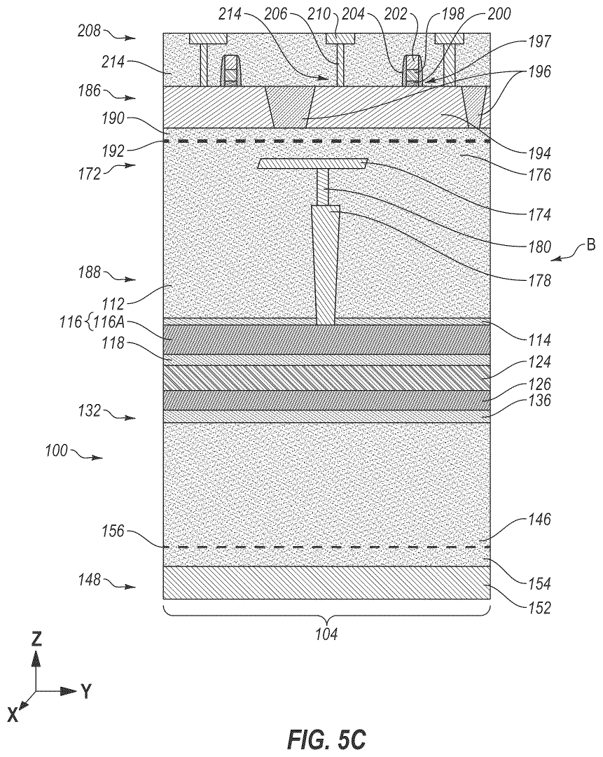

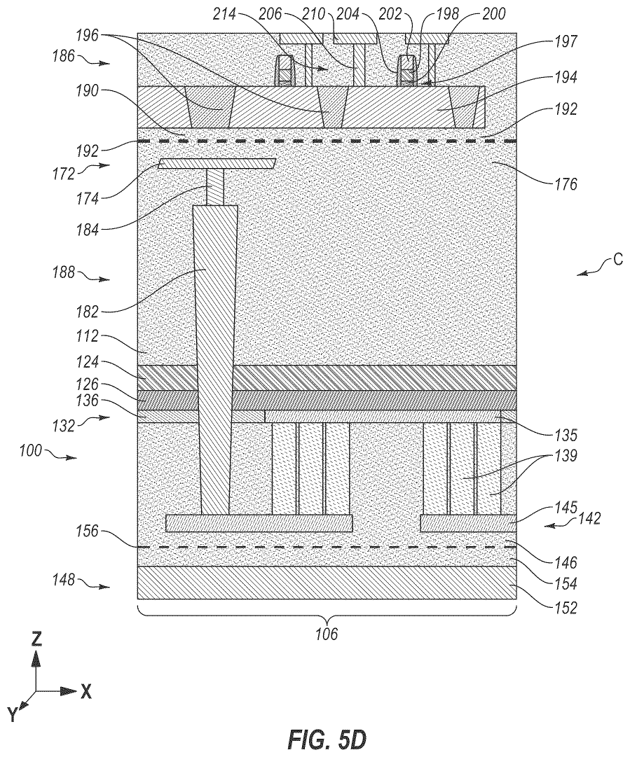

FIGS. 5A through 5D are simplified, partial vertical cross-sectional views of the array region 102 (FIGS. 5A and 5B), the WL exit region 104 (FIG. 5C), and the peripheral region 106 (FIG. 5D) at another processing stage of the method of forming the microelectronic device following the processing stage previously described with reference to FIGS. 4A through 4E. FIG. 5A shows a simplified, partial vertical cross-sectional view of the array region 102 about line A-A shown in FIG. 1 following the processing previously described with reference to FIGS. 4A through 4E. FIG. 5B shows a simplified, partial vertical cross-sectional view of the array region 102 about line D-D shown in FIG. 1 following the processing previously described with reference to FIGS. 4A through 4E. FIG. 5C shows a simplified, partial vertical cross-sectional view of the WL exit region 104 about line B-B shown in FIG. 1 following the processing previously described with reference to FIGS. 4A through 4E. FIG. 5D shows a simplified, partial vertical cross-sectional view of the peripheral region 106 about line C-C shown in FIG. 1 following the processing previously described with reference to FIGS. 4A through 4E.

A second microelectronic device structure 186 (e.g., a second wafer, a second die) may be attached (e.g., bonded) to the fourth isolation material 176 to form a second assembly 188. As described in further detail below, the second microelectronic device structure 186 may include a second base semiconductor structure 194, a fifth isolation material 190 formed on a first side (e.g., a back side) of the second base semiconductor structure 194, and transistors 197 formed at a second, opposing side (e.g., a front side) of the second base semiconductor structure 194. The fifth isolation material 190 of the second microelectronic device structure 186 may be attached (e.g., bonded) to the fourth isolation material 176 to form the second assembly 188. A front side of the second microelectronic device structure 186 may be considered to be a side (e.g., end surface) most proximate to the transistors 197, and a back side of the second microelectronic device structure 186 may be considered to be an additional side (e.g., additional end surface) relatively more distal from the transistors 197 (e.g., most proximate to the fifth isolation material 190) than the front side. In addition, a front side of the first assembly 150 (FIGS. 4A through 4E) following the processing stage previously described with reference to FIGS. 4A through 4E may be considered to be a side (e.g., end surface) most proximate to the first storage node devices 138 of the memory cells 140, and a back side of the first assembly 150 (FIGS. 4A through 4E) following the processing stage previously described with reference to FIGS. 4A through 4E may be considered to be an additional side (e.g., additional end surface) most proximate to the HDL structures 162 (FIGS. 4A through 4C). Accordingly, in the configuration shown in FIGS. 5A through SD, the second assembly 188 may be formed to have a so-called “back-to-back” (B2B) arrangement of the second microelectronic device structure 186 relative to first assembly 150 (FIGS. 4A through 4E) following the processing stage previously described with reference to FIGS. 4A through 4E.

Referring collectively to FIGS. 5A through 5D, the second base semiconductor structure 194 of the second microelectronic device structure 186 comprises a base material or construction upon which additional features (e.g., materials, structures, devices) of the second microelectronic device structure 186 are formed. The second base semiconductor structure 194 may comprise a semiconductor structure (e.g., a semiconductor wafer), or a base semiconductor material on a supporting structure. For example, the second base semiconductor structure 194 may comprise a conventional silicon substrate (e.g., a conventional silicon wafer), or another bulk substrate comprising a semiconductor material. In some embodiments, the second base semiconductor structure 194 comprises a silicon wafer. The second base semiconductor structure 194 may include one or more layers, structures, and/or regions formed therein and/or thereon.

Filled trenches may be formed to vertically extend through second base semiconductor structure 194 and may horizontally neighbor the transistors 197 of the second microelectronic device structure 186. The filled trenches may respectively include a sixth isolation material 196. In some embodiment, the sixth isolation material 196 of the filled trenches vertically extends completely through the second base semiconductor structure 194 to the fifth isolation material 190. The sixth isolation material 196 may be formed of and include at least one insulative material. By way of non-limiting example, the sixth isolation material 196 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the sixth isolation material 196 is formed of and includes SiOₓ (e.g., SiO₂). The sixth isolation material 196 may be substantially homogeneous, or the sixth isolation material 196 may be heterogeneous.

The fifth isolation material 190 of the second microelectronic device structure 186 may be formed of and include at least one insulative material. A material composition of the fifth isolation material 190 may be substantially the same as a material composition of the fourth isolation material 176; or the material composition of the fifth isolation material 190 may be different than the material composition of the fourth isolation material 176. In some embodiments, the fifth isolation material 190 is formed of and includes a dielectric oxide material, such as SiOₓ (e.g., SiO₂). The fifth isolation material 190 may be substantially homogeneous, or the third isolation material 154 may be heterogeneous.

The transistors 197 of the second microelectronic device structure 186 may individually be formed to include conductively doped regions (e.g., a source region and a drain region), a channel region, a gate structure 198, and a gate dielectric material 200. The conductively doped regions may be formed within the second base semiconductor structure 194; the channel region may be formed within the second base semiconductor structure 194 and may be horizontally interposed (e.g., in the X-direction) between the conductively doped regions; the gate structure 198 may vertically overlie (e.g., in the Z-direction) and horizontally overlap (e.g., in the X-direction) the channel region; and the gate dielectric material 200 (e.g., dielectric oxide material) may be vertically interposed (e.g., in the Z-direction) between the gate structure 198 and the channel region.

For an individual transistor 197, the conductively doped regions (e.g., source region, drain region) thereof may include semiconductor material of the second base semiconductor structure 194 doped with one or more desired conductivity enhancing species. In some embodiments, the conductively doped regions of the transistor 197 comprise semiconductor material (e.g., silicon) doped with at least one N-type dopant (e.g., one or more of phosphorus, arsenic, antimony, and bismuth). In some of such embodiments, the channel region of the transistor 197 includes the semiconductor material doped with at least one P-type dopant (e.g., one or more of boron, aluminum, and gallium). In some other of such embodiments, the channel region of the transistor 197 comprises substantially undoped semiconductor material (e.g., substantially undoped silicon). In additional embodiments, for an individual transistor 197, the conductively doped regions thereof comprise semiconductor material (e.g., silicon) doped with at least one P-type dopant (e.g., one or more of boron, aluminum, and gallium). In some of such additional embodiments, the channel region of the transistor 197 comprises the semiconductor material doped with at least one N-type dopant (e.g., one or more of phosphorus, arsenic, antimony, and bismuth). In some other of such additional embodiments, the channel region of the transistor 197 comprises substantially undoped semiconductor material (e.g., substantially undoped silicon).

The gate structures 198 (e.g., gate electrodes) may individually horizontally extend (e.g., in the Y-direction) between and be employed by multiple transistors 197. The gate structures 198 may be formed of and include conductive material. In some embodiments, the gate structures 198 are individually formed of and include one or more of W, Ru, Mo, and TiN_{y}.

As shown in FIGS. 5A through 5D, the second microelectronic device structure 186 may further include gate capping structures 202 on or over the gate structures 198, and spacer structures 204 on sidewalls of at least the gate structures 198 and the gate capping structures 202. The gate capping structures 202 and the spacer structures 204 may individually be formed of and include insulative material. In some embodiments, the gate capping structures 202 are formed of and include dielectric nitride material (e.g., SiN_{y}, such as Si₃N₄), and the spacer structures 204 are formed of and include dielectric oxide material (e.g., SiOₓ, such as SiO₂).

With continued reference to FIGS. 5A through 5D, the second microelectronic device structure 186 may be formed to further include fifth contact structures 206 over and in contact (e.g., physical contact, electrical contact) with the conductively doped regions of the transistors 197, and a third routing tier 208 including third routing structures 210 over and in contact with the fifth contact structures 206. Each of the fifth contact structures 206 and the third routing structures 210 may individually be formed of and include conductive material. In some embodiments, the fifth contact structures 206 and the third routing structures 210 are individually formed of and include one or more of W, Ru, Mo, and TiN_{y}.

The transistors 197, the fifth contact structures 206, and the third routing structures 210 may form various control logic devices of the second microelectronic device structure 186. The control logic devices may individually include control logic circuitry, such as complementary metal-oxide-semiconductor (CMOS) circuitry. Following formation of the second assembly 188, the control logic devices may facilitate desirable control operations for the memory cells 140 (FIGS. 5A and 5B). For example, for the array regions 102 (FIGS. 5A and 5B), the aforementioned features may form and be included within sense amplifier (SA) devices 212 (FIGS. 5A and 5B) for use and operation of the memory cells 140 (FIGS. 5A and 5B). As another example, for the WL exit regions 104 (FIG. 5C), the aforementioned features may form and be included within sub-word line (SWD) devices 215 (FIG. 5C) for use and operation of the memory cells 140 (FIGS. 5A and 5B). As another example, for the peripheral regions 106 (FIG. 5D), the aforementioned features may form and be included within additional control logic devices 216 (FIG. 5D) for use and operation of the memory cells 140 (FIGS. 5A and 5B). Such additional control logic devices 216 (FIG. 5D) may include, without limitation, one or more of driver devices (e.g., column driver(s)), switch devices (e.g., block switch(es)), data path devices, I/O c devices, pump devices (e.g., charge pumps, such as V_{CCP} charge pumps, V_{NEGWL} charge pumps, DVC2 charge pumps; voltage pumps), DLL devices, V_{dd} regulator devices, string driver devices, page buffer devices, decoder (e.g., local deck decoder, column decoder) devices, repair devices (e.g., row repair devices), memory test devices, MUX devices, error correction code (ECC) devices, and self-refresh/wear leveling devices, and various chip/deck control devices.

Still referring collectively to FIGS. 5A through 5D, the second microelectronic device structure 186 may further include a seventh isolation material 214 formed on or over portions of the second base semiconductor structure 194, the sixth isolation material 196, the transistors 197, the fifth contact structures 206, the third routing structures 210, the SA devices 212 (FIGS. 5A and 5B), the SWD devices 215 (FIG. 5C), and the additional control logic devices 216 (FIG. 5D). The seventh isolation material 214 may be formed of and include at least one insulative material. In some embodiments, the seventh isolation material 214 is formed of and includes dielectric oxide material, such as SiOₓ (e.g., SiO₂). The seventh isolation material 214 may be substantially homogeneous, or the seventh isolation material 214 may be heterogeneous. An upper surface of the seventh isolation material 214 may be formed to be substantially planar, and may vertically overlie upper surfaces of the third routing structures 210 (FIGS. 5A through 5D) of the third routing tier 208 (FIGS. 5A through 5D).

To attach the fifth isolation material 190 of the second microelectronic device structure 186 to the fourth isolation material 176 to form the second assembly 188, the fifth isolation material 190 may be provided in physical contact with the fourth isolation material 176 at a second interface 192, and the fourth isolation material 176 and the fifth isolation material 190 may be exposed to annealing conditions to form bonds (e.g., oxide-to-oxide bonds) between the fourth isolation material 176 and the fifth isolation material 190. By way of non-limiting example, the fourth isolation material 176 and the fifth isolation material 190 may be exposed to a temperature greater than or equal to about 400° C. (e.g., within a range of from about 400° C. to about 800° C., greater than about 800° C.) to form oxide-to-oxide bonds between the fourth isolation material 176 and the fifth isolation material 190. In some embodiments, the fourth isolation material 176 and the fifth isolation material 190 are exposed to at least one temperature greater than about 800° C. to form oxide-to-oxide bonds between the fourth isolation material 176 and the fifth isolation material 190. In FIGS. 5A through 5D, the fourth isolation material 176 and the fifth isolation material 190 are distinguished from one another by way of a dashed line representing the second interface 192 therebetween prior to bonding. However, the fourth isolation material 176 and the fifth isolation material 190 may be integral and continuous with one another following the bonding process. The fifth isolation material 190 may be attached to the fourth isolation material 176 without a bond line.

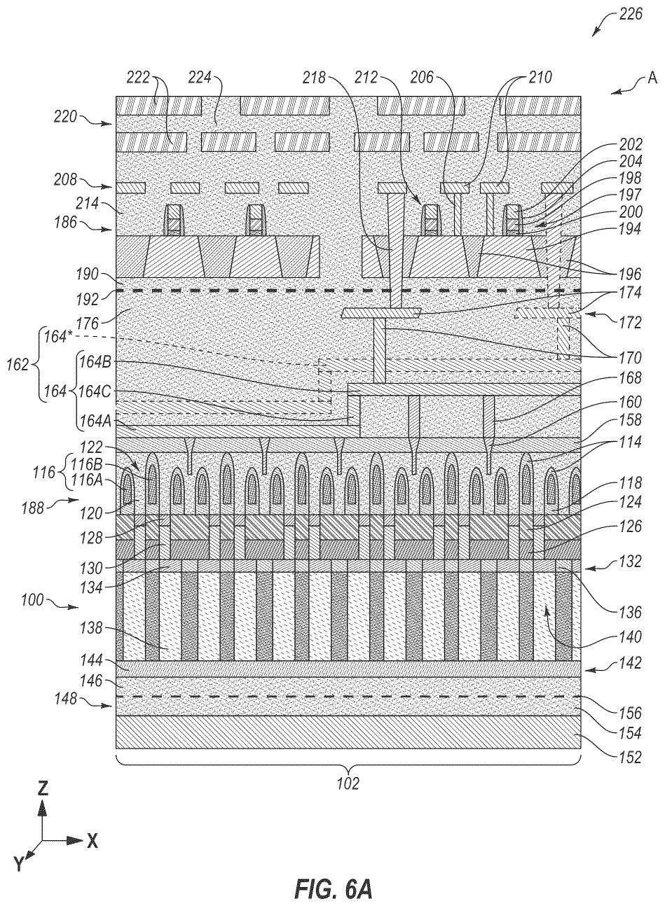

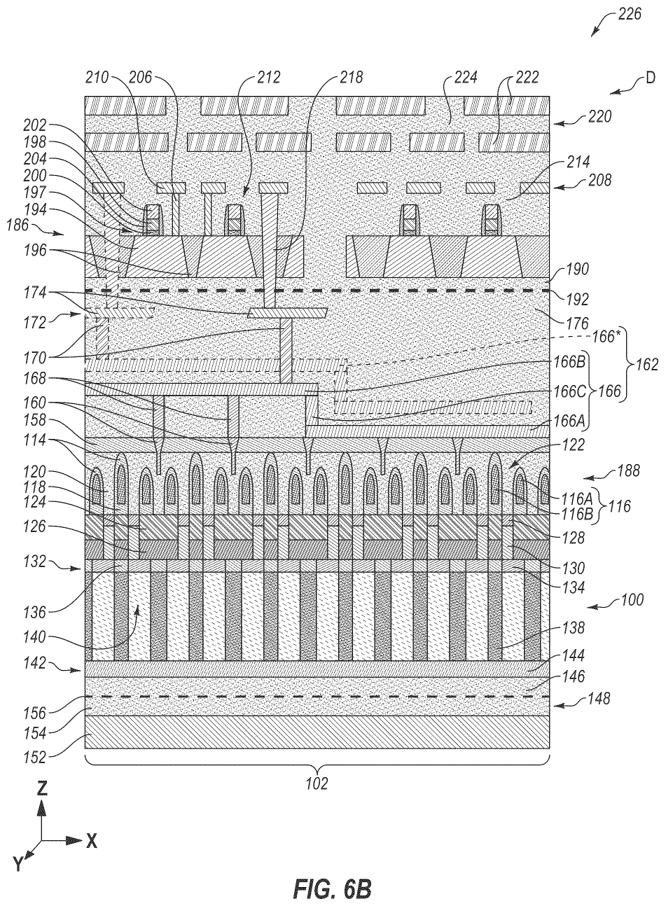

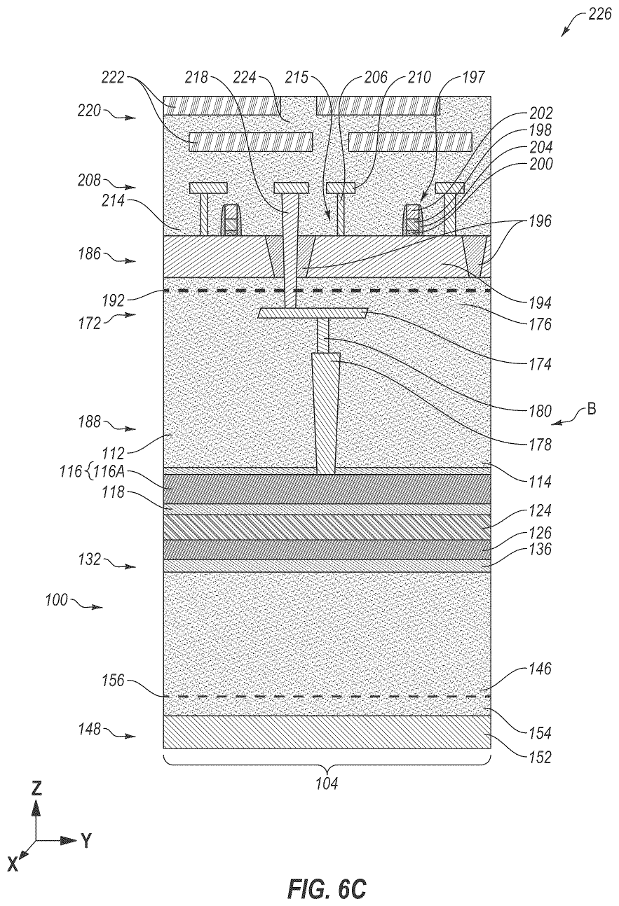

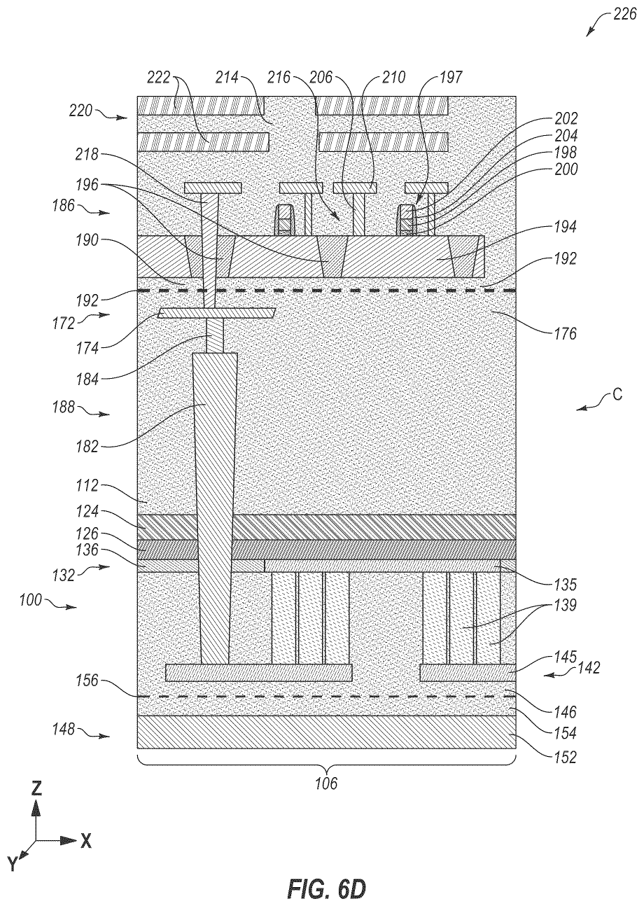

FIGS. 6A through 6D are simplified, partial vertical cross-sectional views of the array region 102 (FIGS. 6A and 6B), the WL exit region 104 (FIG. 6C), and the peripheral region 106 (FIG. 6D) at another processing stage of the method of forming the microelectronic device following the processing stage previously described with reference to FIGS. 5A through 5D. FIG. 6A shows a simplified, partial vertical cross-sectional view of the array region 102 about line A-A shown in FIG. 1 following the processing previously described with reference to FIGS. 5A through 5D. FIG. 6B shows a simplified, partial vertical cross-sectional view of the array region 102 about line D-D shown in FIG. 1 following the processing previously described with reference to FIGS. 5A through 5D. FIG. 6C shows a simplified, partial vertical cross-sectional view of the WL exit region 104 about line B-B shown in FIG. 1 following the processing previously described with reference to FIGS. 5A through 5D. FIG. 6D shows a simplified, partial vertical cross-sectional view of the peripheral region 106 about line C-C shown in FIG. 1 following the processing previously described with reference to FIGS. 5A through 5D.

Referring collectively to FIGS. 6A through 6D, sixth contact structures 218 may be formed to vertically extend (e.g., in the Z-direction) through the seventh isolation material 214 and the sixth isolation material 196 and to or into the second routing structures 174 of the second routing tier 172. The sixth contact structures 218 may individually be formed of and include conductive material. In some embodiments, the sixth contact structures 218 are individually formed of and include one or more of W, Ru, Mo, and TiN_{y}.

Referring to FIGS. 6A and 6B, within the array region 102, a group of the sixth contact structures 218 may be employed to couple to some of the HDL structures 162 to some of the SA devices 212. The group of the sixth contact structures 218 may, for example, contact (e.g., physically contact, electrically contact) a group of the second routing structures 174 contacting a group of the third DL contact structures 170 in electrical communication with the HDL structures 162. Some of the third routing structures 210 and/or additional conductive interconnect (e.g., routing and contact) structures may be employed to facilitate electrical communication between the group of the sixth contact structures 218 and the SA devices 212. As shown in FIG. 6A, some of the sixth contact structures 218 may be employed to couple to the first HDL structures 164, 164* to some of the SA devices 212 (e.g., first SA devices, such as odd SA devices) within the array region 102. For example, one (1) of the sixth contact structures 218 may be formed to couple one (1) of the first base HDL structures 164 to a first end (e.g., in the Y-direction) of an individual SA device 212 (e.g., a first SA device, such as an odd SA device) and another one (1) of the sixth contact structures 218 may be formed to couple one (1) of the first complementary HDL structures 164* to a second, opposite end (e.g., in the Y-direction) of the individual SA device 212. As shown in FIG. 6B, some other of the sixth contact structures 218 may be employed to couple to the second HDL structures 166, 166* to some other of the SA devices 212 (e.g., second SA devices, such as even SA devices) within the array region 102. For example, an additional one (1) of the sixth contact structures 218 may be formed to couple one (1) of the second base HDL structures 166 to a first end (e.g., in the Y-direction) of another individual SA device 212 (e.g., a second SA device, such as an even SA device) and a further one (1) of the sixth contact structures 218 may be formed to couple one (1) of the second complementary HDL structures 166* to a second, opposite end (e.g., in the Y-direction) of the another individual SA device 212.

Referring to FIG. 6C, within the WL exit region 104, an additional group of the sixth contact structures 218 may be employed to couple to some of the WL structures 116 to some of the SWD devices 215. The additional group of the sixth contact structures 218 may, for example, contact (e.g., physically contact, electrically contact) an additional group of the second routing structures 174 coupled to the second WL contact structures 180 and the first WL contact structures 178 in electrical communication with the WL structures 116. An additional group of the third routing structures 210 and/or further conductive interconnect (e.g., routing and contact) structures may be employed to facilitate electrical communication between the additional group of the sixth contact structures 218 and the SWD devices 215.

Referring to FIG. 6D, within the peripheral region 106, a further group of the sixth contact structures 218 may be employed to couple some of the first additional routing structures 145 (and, hence, at least some of the second storage node devices 139) to some of the additional control logic devices 216. The further group of the sixth contact structures 218 may, for example, contact (e.g., physically contact, electrically contact) a further group of the second routing structures 174 coupled to the fourth contact structures 184 and the third contact structures 182 in electrical communication with the first additional routing structures 145. A further group of the third routing structures 210 and/or yet further conductive interconnect (e.g., routing and contact) structures may be employed to facilitate electrical communication between the further group of the sixth contact structures 218 and the additional control logic devices 216.

After forming the sixth contact structures 218, one of more back-end-of-line (BEOL) tiers 220 may be formed vertically thereover. The BEOL tier(s) 220 may individually include, for example, BEOL routing structures 222. At least some of the BEOL routing structures 222 may be employed as global routing structures configured to receive global signals from an external bus, and to relay the global signals to other features (e.g., structures, devices) thereunder. Additional conductive contact structures may be formed to vertically extend (e.g., in the Z-direction) between and electrically connect at least some of the BEOL routing structures 222 with one another and/or with at least some of the additional features (e.g., control logic devices, such as one or more of the additional control logic devices 216 (FIG. 6D), the SA devices 212 (FIGS. 6A and 6B), the SWD devices 215 (FIG. 6C)) thereunder. The BEOL routing structures 222 may individually be formed of and include conductive material. In some embodiments, the BEOL routing structures 222 are individually formed of and include one or more of W, Ru, Mo, and TiN_{y}.

Referring collectively to FIGS. 6A through 6D, an eighth isolation material 224 formed on or over portions of the BEOL routing structures 222, the seventh isolation material 214, and the third routing structures 210. The eighth isolation material 224 may be formed of and include at least one insulative material. In some embodiments, the eighth isolation material 224 is formed of and includes dielectric oxide material, such as SiOₓ (e.g., SiO₂). The eighth isolation material 224 may be substantially homogeneous, or the eighth isolation material 224 may be heterogeneous.

As shown in FIGS. 6A through 6D, the method described above with reference to FIGS. 1 through 6D may effectuate the formation of a microelectronic device 226 (e.g., a memory device, such as a DRAM device) including the features (e.g., structures, materials, devices) previously described herein. The configuration of the microelectronic device 226, including, without limitation, the configurations of the HDL structures 162 and the positions of the first storage node devices 138 and the HDL structures 162 relative to one another and the access devices 122, may advantageously reduce one or more of conductive routing complexity, undesirable parasitic coupling, sense margin noise, and array efficiency penalties (e.g., resulting from conventional higher aspect ratio contacts and relatively larger associated socket sizes) as compared to conventional microelectronic device configurations.

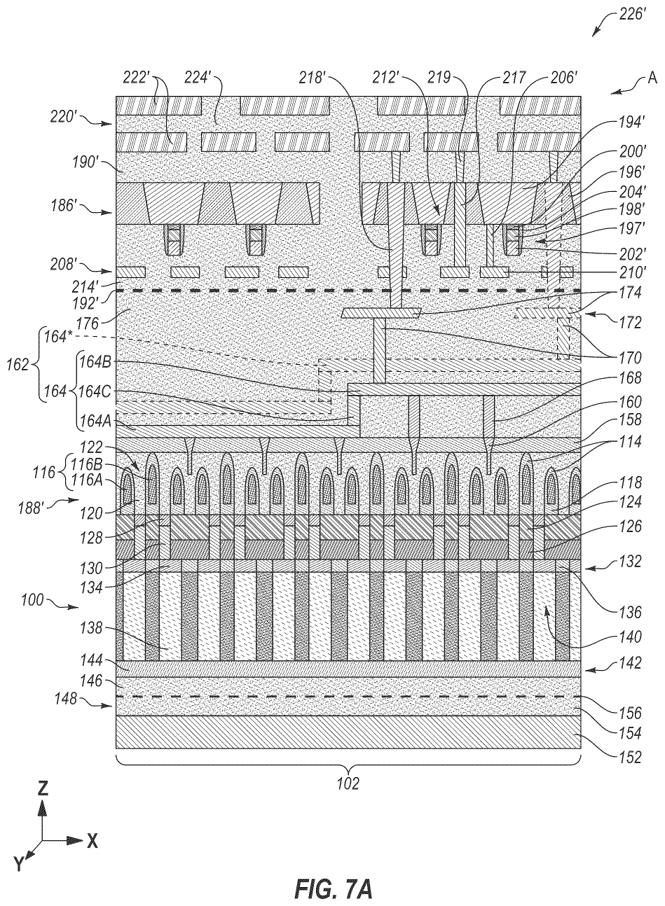

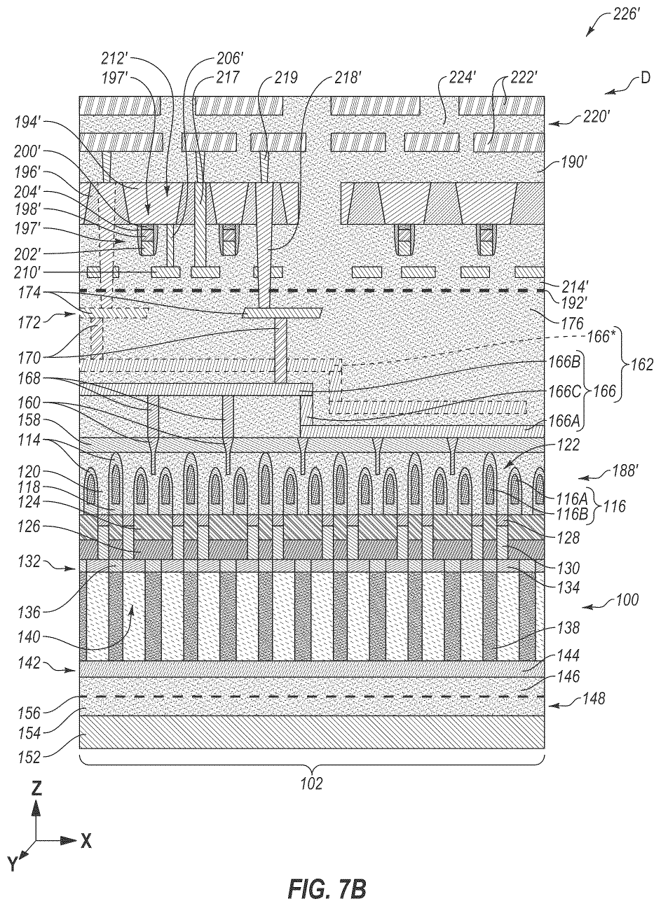

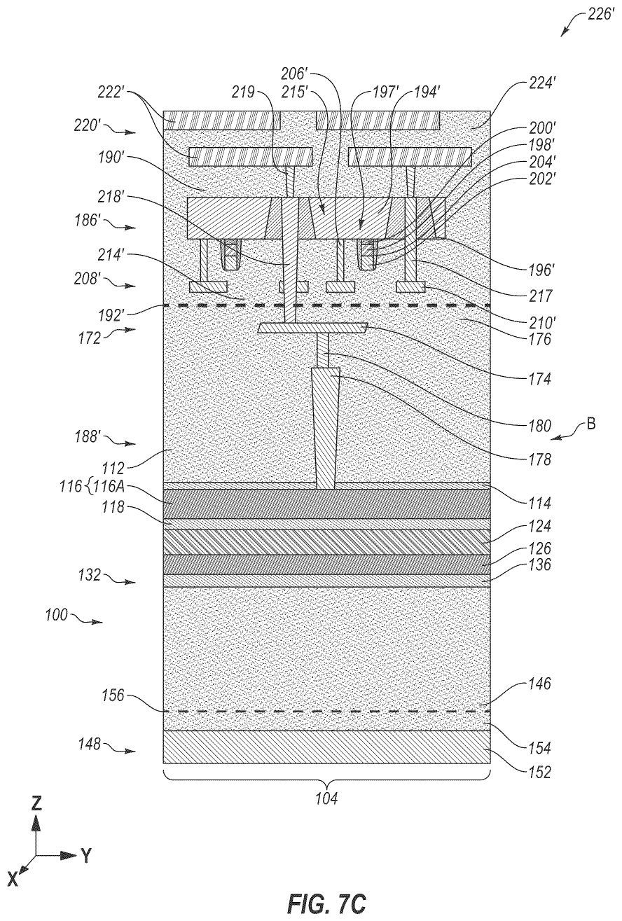

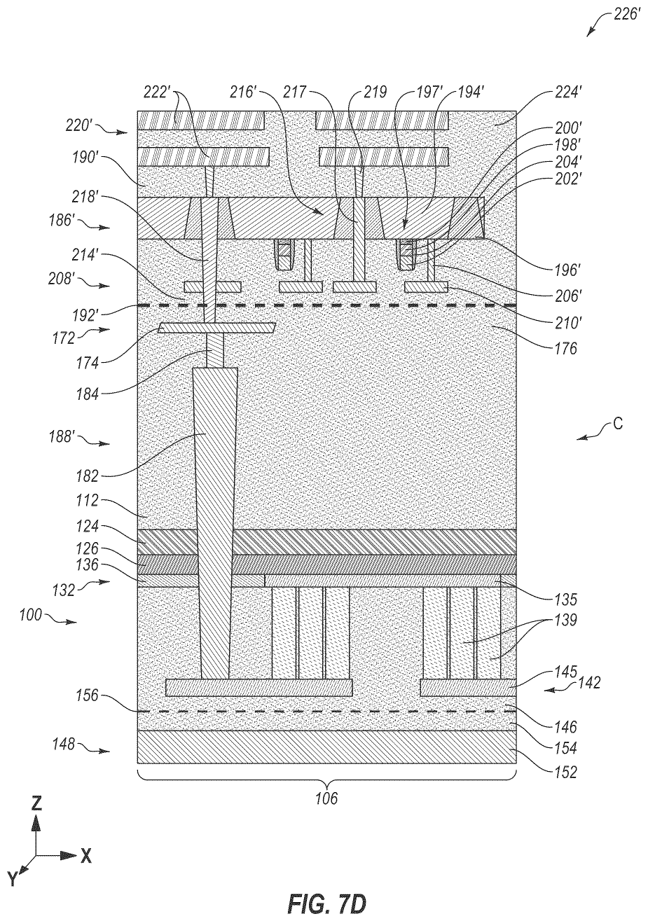

In additional embodiments, some of processing acts and stages previously described herein with reference to FIGS. 6A through 6D may modified to form a microelectronic device of the disclosure having a different configuration than the microelectronic device 226 (FIGS. 6A through 6D). For example, FIGS. 7A through 7D are various views (described in further detail below) of a microelectronic device 226′ of the disclosure formed in accordance with an additional method of the disclosure. The method of forming the microelectronic device 226′ may include the processing acts and processing stages previously described herein with reference to FIGS. 1 through 4E, but processing acts and stages following the processing previously described herein with reference to FIGS. 4A through 4E may be modified relative to the processing previously described herein with reference to FIGS. 5A through 6D. FIG. 7A shows a simplified, partial vertical cross-sectional view of the array region 102 about line A-A shown in FIG. 1 following the processing previously described with reference to FIGS. 4A through 4E. FIG. 7B shows a simplified, partial vertical cross-sectional view of the array region 102 about line D-D shown in FIG. 1 following the processing previously described with reference to FIGS. 4A through 4E. FIG. 7C shows a simplified, partial vertical cross-sectional view of the WL exit region 104 about line B-B shown in FIG. 1 following the processing previously described with reference to FIGS. 4A through 4E. FIG. 7D shows a simplified, partial vertical cross-sectional view of the peripheral region 106 about line C-C shown in FIG. 1 following the processing previously described with reference to FIGS. 4A through 4E.

To avoid repetition, not all features shown in FIGS. 7A through 7D are described in detail herein. Rather, in FIGS. 7A through 7D, unless otherwise described, a feature designated by a reference numeral that as a prime (′) of a reference numeral of a previously described feature will be understood to be substantially similar to the previously described feature and will also be understood to be formed in substantially the same manner as the previously described feature. By way of non-limiting example, in FIGS. 7A through 7D, a second microelectronic device structure 186′, a fifth isolation material 190′, a second base semiconductor structure 194′, transistors 197′, fifth contact structures 206′, third routing structures 210′, SA devices 212′ (FIGS. 7A and 7B), SWD devices 215′ (FIG. 7C), additional control logic devices 216′ (FIG. 7D), and BEOL routing structures 222′ may respectively be substantially similar to and may formed in substantially the same manner as the second microelectronic device structure 186, the fifth isolation material 190, the second base semiconductor structure 194, transistors 197, the fifth contact structures 206, the third routing structures 210, the SA devices 212, SWD devices 215, the additional control logic devices 216, and the BEOL routing structures 222 previously described herein with reference to one or more of FIGS. 5A through 6D.

Referring collectively to FIGS. 7A through 7D, the second microelectronic device structure 186′ may be attached to the (e.g., bonded) to the fourth isolation material 176 such that the resulting second assembly 188′ has a so-called “front-to-back” (F2B) arrangement of the second microelectronic device structure 186′ relative to first assembly 150 (FIGS. 4A through 4E) following the processing stage previously described with reference to FIGS. 4A through 4E. For example, the second microelectronic device structure 186′ may be vertically inverted relative to the orientation of the second microelectronic device structure 186 previously described with reference to FIGS. 5A through 5D, and the seventh isolation material 214′ may be attached (e.g., bonded) to the fourth isolation material 176. Accordingly, following attachment of the second microelectronic device structure 186′ to the fourth isolation material 176, features of the second microelectronic device structure 186′ may be vertically inverted (e.g., vertically flipped, rotated 180 degrees) relative to the second microelectronic device structure 186 previously described with reference to FIGS. 5A through 5D. For example, gate structures 198′ of the transistors 197′ of the second microelectronic device structure 186′ may be located relatively more proximate to the HDL structures 162 than the gate structures 198 of the transistors 197 of the second microelectronic device structure 186 previously described with reference to FIGS. 5A through 5D. In addition, the second base semiconductor structure 194′ of the second microelectronic device structure 186′, which includes channel regions and source/drain regions of the transistors 197′ therein, may be located relatively more distal from the HDL structures 162 than the second base semiconductor structure 194 of the second microelectronic device structure 186 previously described with reference to FIGS. 5A through 5D.

To attach the seventh isolation material 214′ of the second microelectronic device structure 186′ to the fourth isolation material 176 to form the second assembly 188′, the seventh isolation material 214′ may be provided in physical contact with the fourth isolation material 176 at a second interface 192′, and the fourth isolation material 176 and the seventh isolation material 214′ may be exposed to annealing conditions to form bonds (e.g., oxide-to-oxide bonds) between the fourth isolation material 176 and the seventh isolation material 214′. By way of non-limiting example, the fourth isolation material 176 and the seventh isolation material 214′ may be exposed to a temperature greater than or equal to about 400° C. (e.g., within a range of from about 400° C. to about 800° C., greater than about 800° C.) to form oxide-to-oxide bonds between the fourth isolation material 176 and the seventh isolation material 214′. In some embodiments, the fourth isolation material 176 and the seventh isolation material 214′ are exposed to at least one temperature greater than about 800° C. to form oxide-to-oxide bonds between the fourth isolation material 176 and the seventh isolation material 214′. In FIGS. 7A through 7D, the fourth isolation material 176 and the seventh isolation material 214′ are distinguished from one another by way of a dashed line representing the second interface 192 therebetween prior to bonding. However, the fourth isolation material 176 and the seventh isolation material 214′ may be integral and continuous with one another following the bonding process. The seventh isolation material 214′ may be attached to the fourth isolation material 176 without a bond line.

After forming the second assembly 188′, the sixth contact structures 218′ may be formed to vertically extend through portions of the fifth isolation material 190′, the sixth isolation material 196′, the seventh isolation material 214′, and the fourth isolation material 176, and to or into at least some of the second routing structures 174 of the second routing tier 172. As shown in FIGS. 7A through 7D, at least some of the sixth contact structures 218′ may also be formed to vertically extend through (e.g., penetrate through) some of the third routing structures 210′ of the third routing tier 208′. In addition, seventh contact structures 217 may be formed to vertically extend through additional portions of the fifth isolation material 190′, the sixth isolation material 196′, the seventh isolation material 214′, and the fourth isolation material 176, and to or into at least some of the third routing structures 210′ of the third routing tier 208′. The sixth contact structures 218′ and the seventh contact structures 217 may individually be formed of and include conductive material. In some embodiments, the sixth contact structures 218′ and the seventh contact structures 217 are individually formed of and include one or more of W, Ru, Mo, and TiN_{y}. In embodiments where sixth contact structures 218′ vertically extend through (e.g., penetrate through) some of the third routing structures 210′ of the third routing tier 208′, a dielectric liner material may be formed between the sixth contact structures 218′ and the third routing structures 210′ to electrically isolate the sixth contact structures 218′ from the third routing structures 210′.

Following the formation of the sixth contact structures 218′ and the seventh contact structures 217, eighth isolation material 224′ and BEOL tiers 220′ including BEOL routing structures 222′ may be formed over a back side of the second base semiconductor structure 194′. In addition, eighth contact structures 219 may be formed to vertically extend between some of the BEOL routing structures 222′ and some of the sixth contact structures 218′ and the seventh contact structures 217. The eighth contact structures 219 may be formed prior the formation of the BEOL routing structures 222′, and may couple the some of the BEOL routing structures 222′ to some of the sixth contact structures 218′ and some of the seventh contact structures 217, as described in further detail below. The eighth contact structures 219 may be formed of and include conductive material. In some embodiments, the eighth contact structures 219 are individually formed of and include one or more of W, Ru, Mo, and TiN_{y}.

Referring to FIGS. 7A and 7B, within the array region 102, a combination of some of the sixth contact structures 218′, some of the seventh contact structures 217, some of the eighth contact structures 219, and some of the BEOL routing structures 222′ may be employed to couple to some of the HDL structures 162 to some of the SA devices 212′. A group of the sixth contact structures 218′ may, for example, contact (e.g., physically contact, electrically contact) a group of the second routing structures 174 contacting a group of the third DL contact structures 170 in electrical communication with the HDL structures 162. Furthermore, electrical communication between the group of the sixth contact structures 218′ and the SA devices 212′ may be facilitated by a combination of some of the eighth contact structures 219, some of the BEOL routing structures 222′, some of the seventh contact structures 217, and some of the third routing structures 210′. As shown in FIG. 7A, some of the sixth contact structures 218′ may be employed to couple to the first HDL structures 164, 164* to some of the SA devices 212′ (e.g., first SA devices, such as odd SA devices) within the array region 102. For example, one (1) of the sixth contact structures 218′ may be formed to couple one (1) of the first base HDL structures 164 to a first end (e.g., in the Y-direction) of an individual SA device 212′ (e.g., a first SA device, such as an odd SA device) and another one (1) of the sixth contact structures 218′ may be formed to couple one (1) of the first complementary HDL structures 164* to a second, opposite end (e.g., in the Y-direction) of the individual SA device 212′. As shown in FIG. 7B, some other of the sixth contact structures 218′ may be employed to couple to the second HDL structures 166, 166* to some other of the SA devices 212′ (e.g., second SA devices, such as even SA devices) within the array region 102. For example, an additional one (1) of the sixth contact structures 218′ may be formed to couple one (1) of the second base HDL structures 166 to a first end (e.g., in the Y-direction) of another individual SA device 212′ (e.g., a second SA device, such as an even SA device) and a further one (1) of the sixth contact structures 218 may be formed to couple one (1) of the second complementary HDL structures 166* to a second, opposite end (e.g., in the Y-direction) of the another individual SA device 212′.

Referring to FIG. 7C, within the WL exit region 104, an additional combination of some other of the sixth contact structures 218′, some other of the seventh contact structures 217, some other of the eighth contact structures 219, and some other of the BEOL routing structures 222′ may be employed to couple to some of the WL structures 116 to some of the SWD devices 215′. An additional group of the sixth contact structures 218′ may, for example, contact (e.g., physically contact, electrically contact) an additional group of the second routing structures 174 coupled to the second WL contact structures 180 and the first WL contact structures 178 in electrical communication with the WL structures 116. Furthermore, electrical communication between the additional group of the sixth contact structures 218′ and the SWD devices 215′ may be facilitated by a combination of some other of the eighth contact structures 219, some other of the BEOL routing structures 222′, some other of the seventh contact structures 217, and some other of the third routing structures 210′.

Referring to FIG. 7D, within the peripheral region 106, a further combination of some more of the sixth contact structures 218′, some more of the seventh contact structures 217, some more of the eighth contact structures 219, and some more of the BEOL routing structures 222′ may be employed to couple to some of the first additional routing structures 145 (and, hence, at least some of the second storage node devices 139) to some of the additional control logic devices 216′. A further group of the sixth contact structures 218′ may, for example, contact (e.g., physically contact, electrically contact) a further group of the second routing structures 174 coupled to the fourth contact structures 184 and the third contact structures 182 in electrical communication with the first additional routing structures 145. Furthermore, electrical communication between the further group of the sixth contact structures 218′ and the additional control logic devices 216′ may be facilitated by a combination of some more of the eighth contact structures 219, some more of the BEOL routing structures 222′, some more of the seventh contact structures 217, and some more of the third routing structures 210′.

Thus, in accordance with embodiments of the disclosure, a microelectronic device includes memory cells, hieratical digit line (HDL) structures, and sense amplifier (SA) devices. The memory cells are within an array region and respectively include an access device and a storage node device vertically underlying and coupled to the access device. The HDL structures are within the array region and vertically overlie and are coupled to the memory cells. The HDL structures respectively include a lower section, an upper section vertically overlying and at least partially horizontally offset from the lower section, and a middle section vertically extending from and between the lower section and the upper section. The SA devices are within the array region and vertically overlie and are coupled to the HDL structures.

Furthermore, in accordance with embodiments of the disclosure, a method of forming a microelectronic device includes forming a first microelectronic device structure including an array region having memory cells respectively including an access device and a capacitor vertically overlying and coupled to the access device. The first microelectronic device structure is vertically inverted. Contact structures are formed within the array region and are coupled to the memory cells after vertically inverting the first microelectronic device structure.

Hieratical digit line (HDL) structures are within the array region and vertically overlie and are coupled to the contact structures. The HDL structures respectively include a lower section, an upper section vertically overlying and horizontally offset from the lower section, and a middle section vertically between the lower section and the upper section. A second microelectronic device structure including sense amplifier (SA) devices is attached over the HDL structures. The SA devices are positioned within the array region after attaching the second microelectronic device structure over the HDL structures. The SA devices are coupled to the HDL structures.

Moreover, in accordance with embodiments of the disclosure, a memory device includes an array region and a word line (WL) exit region. The array region includes memory cells, WL structures, hieratical digit line (HDL) structures, and sense amplifier (SA) devices. The memory include access devices vertically overlying and coupled to capacitors. The WL structures vertically overlie the capacitors of the memory cells and horizontally extend in parallel in a first direction. The HDL structures vertically overlie the WL structures and are coupled to the access devices of the memory cells. The HDL structures horizontally extend in parallel in a second direction orthogonal to the first direction and respectively include a first section, a second section vertically underlying and horizontally offset from the first section in the second direction, and a third section vertically extending from the first section to the second section. The SA devices vertically overlie and are coupled to the HDL structures. WL exit region horizontally neighbors the array region in the second direction and includes portions of the WL structures and sub-word line driver (SWD) devices. The SWD devices vertically overlie and are coupled to the portions of the WL structures.

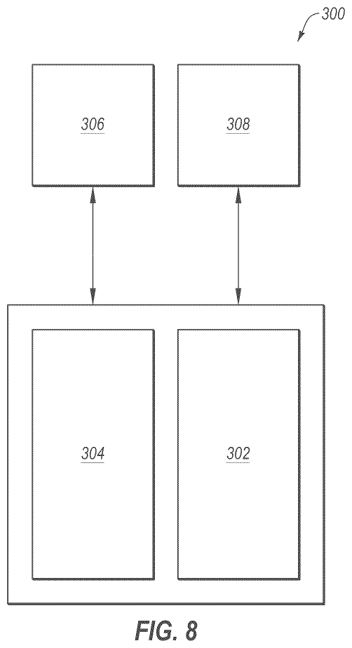

Microelectronic devices (e.g., the microelectronic device 226 (FIGS. 6A through 6D); the microelectronic device 226′ (FIGS. 7A through 7D)) in accordance with embodiments of the disclosure may be used in embodiments of electronic systems of the disclosure. For example, FIG. 8 is a block diagram illustrating an electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, a microelectronic device (e.g., the microelectronic device 226 (FIGS. 6A through 6D); the microelectronic device 226′ (FIGS. 7A through 7D)) previously described herein. The electronic system 300 may further include at least one electronic signal processor device 304 (often referred to as a “microprocessor”). The electronic signal processor device 304 may, optionally, comprise a microelectronic device (e.g., the microelectronic device 226 (FIGS. 6A through 6D); the microelectronic device 226′ (FIGS. 7A through 7D)) previously described herein. While the memory device 302 and the electronic signal processor device 304 are depicted as two (2) separate devices in FIG. 8, in additional embodiments, a single (e.g., only one) memory/processor device having the functionalities of the memory device 302 and the electronic signal processor device 304 is included in the electronic system 300. In such embodiments, the memory/processor device may include a microelectronic device (e.g., the microelectronic device 226 (FIGS. 6A through 6D); the microelectronic device 226′ (FIGS. 7A through 7D)) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
memory cells within an array region, the memory cells respectively comprising:
an access device; and
a storage node device vertically underlying and coupled to the access device;
hieratical digit line (HDL) structures within the array region and vertically overlying and coupled to the memory cells, the HDL structures respectively comprising:
a lower section;
an upper section vertically overlying and at least partially horizontally offset from the lower section; and
a middle section vertically extending from and between the lower section and the upper section; and
sense amplifier (SA) devices within the array region and vertically overlying and coupled to the HDL structures.

2. The microelectronic device of claim 1, wherein the memory cells further respectively comprise:
a cell contact coupled to and vertically extending downward from the access device; and
a redistribution material (RDM) structure vertically interposed between and in contact with the cell contact and the storage node device.

3. The microelectronic device of claim 2, further comprising digit line contacts vertically interposed between and in contact with the memory cells and the HDL structures, the digit line contacts individually coupled to and vertically extending upward from the access device of a respective one of the memory cells.

4. The microelectronic device of claim 1, wherein HDL structures comprise:
first HDL structures; and
second HDL structures horizontally extending in parallel with the first HDL structures in a first direction and horizontally alternating with the first HDL structures in a second direction orthogonal to the first direction,
the lower section of at least one of the second HDL structures substantially horizontally overlapping the upper section of at least one of the first HDL structures in the first direction, and
the upper section of the at least one of the second HDL structures substantially horizontally overlapping the lower section of the at least one of the first HDL structures in the first direction.

5. The microelectronic device of claim 4, wherein:
the first HDL structures comprise first base HDL structures and first complementary HDL structures, some of the SA devices individually coupled to a respective one of the first base HDL structures and a respective one of the first complementary HDL structures; and
the second HDL structures comprise second base HDL structures and second complementary HDL structures, some other of the SA devices individually coupled to a respective one of the second base HDL structures and a respective one of the second complementary HDL structures.

6. The microelectronic device of claim 1, wherein the SA devices comprise:
transistors; and
conductive routing structures vertically overlying and coupled to the transistors, the transistors vertically interposed between the conductive routing structures and the HDL structures.

7. The microelectronic device of claim 1, wherein the SA devices comprise:
transistors; and
conductive routing structures vertically underlying and coupled to the transistors, the conductive routing structures vertically interposed between the transistors and the HDL structures.

8. The microelectronic device of claim 1, further comprising sub-word line driver (SWD) devices vertically overlying the HDL structures and within a word line (WL) exit region horizontally neighboring the array region, the SWD devices coupled to WL structures coupled to the memory cells.

9. The microelectronic device of claim 1, further comprising:
capacitor devices within a peripheral region horizontally neighboring the array region; and
additional control logic devices vertically overlying the HDL structures and within the peripheral region, at least some of the additional control logic devices coupled to the capacitor devices.

10. A method of forming a microelectronic device, comprising:
forming a first microelectronic device structure including an array region having memory cells respectively comprising an access device and a capacitor vertically overlying and coupled to the access device;
vertically inverting the first microelectronic device structure;
forming contact structures within the array region and coupled to the memory cells after vertically inverting the first microelectronic device structure;
forming hieratical digit line (HDL) structures within the array region and vertically overlying and coupled to the contact structures, the HDL structures respectively comprising a lower section, an upper section vertically overlying and horizontally offset from the lower section, and a middle section vertically between the lower section and the upper section;
attaching a second microelectronic device structure comprising sense amplifier (SA) devices over the HDL structures, the SA devices positioned within the array region after attaching the second microelectronic device structure over the HDL structures; and
coupling the SA devices to the HDL structures.

11. The method of claim 10, wherein forming a first microelectronic device structure comprises forming the first microelectronic device structure to further include:
a word line (WL) exit region comprising portions of WL structures coupled to the memory cells; and
a peripheral region comprising additional capacitors at a vertical position of the capacitor of respective ones of the memory cells.

12. The method of claim 11, further comprising forming the second microelectronic device structure to further include sub-word line driver (SWD) devices and additional control logic devices horizontally offset from the SA devices,
the SWD devices positioned within the array region after attaching the second microelectronic device structure over the HDL structures, and
the additional control logic devices positioned within the peripheral region after attaching the second microelectronic device structure over the HDL structures.

13. The method of claim 12, further comprising, after attaching the second microelectronic device structure over the HDL structures:
coupling the SWD devices to the WL structures; and
coupling at least some of the additional control logic devices to the additional capacitors.

14. The method of claim 10, wherein forming HDL structures comprises forming the HDL structures to include:
odd HDL structures; and
even HDL structures horizontally extending in parallel with odd HDL structures in a first direction and horizontally alternating with the odd HDL structures in a second direction perpendicular to the first direction,
the lower section of at least one of the even HDL structures substantially horizontally overlapping the upper section of at least one of the odd HDL structures in the first direction, and
the upper section of the at least one of the even HDL structures substantially horizontally overlapping the lower section of the at least one of the odd HDL structures in the first direction.

15. The method of claim 10, wherein attaching a second microelectronic device structure over the HDL structures comprises bonding a dielectric oxide material of the second microelectronic device structure to an additional oxide dielectric material formed over the HDL structures.

16. The method of claim 10, wherein coupling the SA devices to the HDL structures comprises forming additional contact structures vertically extending between and coupling the SA devices and the HDL structures after attaching the second microelectronic device structure over the HDL structures.

17. The method of claim 10, further comprising forming back-end-of-line (BEOL) structures vertically over the SA devices after coupling the SA devices to the HDL structures.

18. A memory device, comprising:
an array region comprising:
memory cells comprising access devices vertically overlying and coupled to capacitors;
word line (WL) structures vertically overlying the capacitors of the memory cells and horizontally extending in parallel in a first direction;
hieratical digit line (HDL) structures vertically overlying the WL structures and coupled to the access devices of the memory cells, the HDL structures horizontally extending in parallel in a second direction orthogonal to the first direction and respectively comprising:
a first section;
a second section vertically underlying and horizontally offset from the first section in the second direction;
a third section vertically extending from the first section to the second section;
sense amplifier (SA) devices vertically overlying and coupled to the HDL structures; and
a WL exit region horizontally neighboring the array region in the second direction and comprising:
portions of the WL structures; and
sub-word line driver (SWD) devices vertically overlying and coupled to the portions of the WL structures.

19. The memory device of claim 18, further comprising a peripheral region horizontally neighboring the array region in the first direction and comprising:
additional capacitors at vertically overlapping the capacitors of the memory cells; and
additional control logic devices vertically overlying and coupled to the additional capacitors.

20. The memory device of claim 18, wherein the HDL structures comprise:
odd HDL structures; and
even HDL structures horizontally alternating with the odd HDL structures in the first direction,
the first section of each of the even HDL structures horizontally overlapping the second section of each of the odd HDL structures in the second direction,
the second section of each of the even HDL structures horizontally overlapping the first section of each of the odd HDL structures in the second direction.
